(19) United States
(12) Patent Application Publication
(10) Pub. No.: US 2025/0040389 A1
(43) Pub. Date: Jan. 30, 2025

(54) DISPLAY PANEL AND FORMATION METHOD THEREOF, AND DISPLAY APPARATUS

(71) Applicant: Wuhan Tianma Micro-Electronics Co., Ltd., Wuhan (CN)

(72) Inventors: Yangzhao MA, Wuhan (CN); Meihong WANG, Wuhan (CN)

(21) Appl. No.: 18/600,790

(22) Filed: Mar. 11, 2024

(30) Foreign Application Priority Data
Jul. 24, 2023 (CN) 202310914733.5

(51) Int. Cl. H10K 59/35; H10K 59/12; H10K 59/121; H10K 59/122; H10K 59/131; H10K 59/38; H10K 59/80

(52) U.S. Cl. CPC H10K 59/353; H10K 59/1201; H10K 59/1213; H10K 59/1216; H10K 59/122; H10K 59/131; H10K 59/352; H10K 59/38; H10K 59/80515; H10K 59/873; H10K 59/8792

(57) ABSTRACT

The present disclosure provides a display panel, a formation method, and a display apparatus. The display panel includes a plurality of sub-pixels, where a sub-pixel includes a first sub-pixel, a second sub-pixel, and a third sub-pixel; and at least the first sub-pixel includes a first main sub-pixel and a first interference sub-pixel. The display panel includes a display mode and an anti-peep mode during operation. In the display mode, the first main sub-pixel emits light, and the first interference sub-pixel does not emit light. In the anti-peep mode, both the first main sub-pixel and the first interference sub-pixel emit light, where the first interference sub-pixel emits light at a wide viewing angle from a light-exiting surface, an angle between the large viewing angle and a first direction is greater than or equal to 30°, and the first direction is a direction perpendicular to a plane of the substrate.

### CROSS-REFERENCE TO RELATED APPLICATION

The present disclosure claims the priority of Chinese Patent Application No. 202310914733.5, filed on Jul. 24, 2023, the content of which is incorporated herein by reference in its entirety.

### TECHNICAL FIELD

The present disclosure generally relates to the field of display technology and, more particularly, relates to a display panel and a formation method thereof, and a display apparatus.

### BACKGROUND

Currently, apparatuses with display panels are used to handle work and daily tasks. Terminal apparatuses have relatively large viewing angles, and users at different viewing angles may obtain the information displayed. In order to prevent the display contents of the display panels from being seen by others to cause inconvenience, anti-peep performance of the display panels are needed.

For liquid crystal display (LCD) panels, anti-peep technology mainly includes an on-state (e.g., white) anti-peep and an off-state (e.g., black) anti-peep. The on-state anti-peep is achieved by increasing dark light leakage at large viewing angles and reducing contrast; and the off-state anti-peep is achieved by adding anti-peep films and dimming films to backlight.

However, due to different structures of liquid crystal display panels and organic self-light-emitting display panels, above-mentioned anti-peep technology cannot be directly applied to organic self-light-emitting display panels. Therefore, there is a need to provide a display panel, a formation method, and a display apparatus that may realize the anti-peep effect of the organic self-light-emitting display panels.

### SUMMARY

One aspect of the present disclosure provides a display panel. The display panel includes a plurality of sub-pixels, where a sub-pixel of the plurality of sub-pixels includes a first sub-pixel, a second sub-pixel, and a third sub-pixel; the first sub-pixel, the second sub-pixel, and the third sub-pixel emit light of different colors; the sub-pixel of the plurality of sub-pixels includes a substrate, a light-emitting structure on a side of the substrate, and an encapsulation layer on a side of the light-emitting structure away from the substrate; at least the first sub-pixel includes a first main sub-pixel and a first interference sub-pixel; and the first interference sub-pixel at least partially surrounds the first main sub-pixel; and includes a display mode and an anti-peep mode during operation. In the display mode, the first main sub-pixel emits light, and the first interference sub-pixel does not emit light; and in the anti-peep mode, both the first main sub-pixel and the first interference sub-pixel emit light, where the first interference sub-pixel emits light at a wide viewing angle from a light-exiting surface, an angle between the large viewing angle and a first direction is greater than or equal to 30°, and the first direction is a direction perpendicular to a plane of the substrate.

Another aspect of the present disclosure provides a formation method of a display panel. The display panel includes a plurality of sub-pixels, where a sub-pixel of the plurality of sub-pixels include a first sub-pixel, a second sub-pixel, and a third sub-pixel; at least the first sub-pixel includes a first main sub-pixel and a first interference sub-pixel; and the first interference sub-pixel at least partially surrounds the first main sub-pixel. The method includes providing a substrate; forming a pixel defining layer and a light-emitting structure on the substrate, where the light-emitting structure is in an opening of the pixel defining layer; forming an encapsulation layer on a side of the light-emitting structure away from the substrate; and at a position corresponding to the first interference sub-pixel, forming a light guide structure on a side of the encapsulation layer away from the substrate, where an orthographic projection of the light guide structure on a plane of the substrate is at least partially overlapped with an orthographic projection of the light-emitting structure on the plane of the substrate; and the light guide structure includes a light-blocking layer.

Another aspect of the present disclosure provides a display apparatus including a display panel. The display panel includes a plurality of sub-pixels, where a sub-pixel of the plurality of sub-pixels includes a first sub-pixel, a second sub-pixel, and a third sub-pixel; the first sub-pixel, the second sub-pixel, and the third sub-pixel emit light of different colors; the sub-pixel of the plurality of sub-pixels includes a substrate, a light-emitting structure on a side of the substrate, and an encapsulation layer on a side of the light-emitting structure away from the substrate; at least the first sub-pixel includes a first main sub-pixel and a first interference sub-pixel; and the first interference sub-pixel at least partially surrounds the first main sub-pixel; and includes a display mode and an anti-peep mode during operation. In the display mode, the first main sub-pixel emits light, and the first interference sub-pixel does not emit light; and in the anti-peep mode, both the first main sub-pixel and the first interference sub-pixel emit light, where the first interference sub-pixel emits light at a wide viewing angle from a light-exiting surface, an angle between the large viewing angle and a first direction is greater than or equal to 30°, and the first direction is a direction perpendicular to a plane of the substrate.

Other aspects of the present disclosure may be understood by those skilled in the art in light of the description, the claims, and the drawings of the present disclosure.

### BRIEF DESCRIPTION OF THE DRAWINGS

The accompanying drawings, which are incorporated into a part of the specification, illustrate embodiments of the present disclosure and together with the description to explain the principles of the present disclosure.

FIG. 1 illustrates a planar structural schematic of a display panel according to various embodiments of the present disclosure.

FIG. 2 illustrates a cross-sectional view along an A-A′ direction in FIG. 1.

FIG. 3 illustrates a schematic of a display panel displaying images in a display mode according to various embodiments of the present disclosure.

FIG. 4 illustrates a schematic of a display panel displaying images in an anti-peep mode according to various embodiments of the present disclosure.

FIG. 5 illustrates another planar structural schematic of a display panel according to various embodiments of the present disclosure.

FIG. 6 illustrates another planar structural schematic of a display panel according to various embodiments of the present disclosure.

FIG. 7 illustrates another planar structural schematic of a display panel according to various embodiments of the present disclosure.

FIG. 8 illustrates another planar structural schematic of a display panel according to various embodiments of the present disclosure.

FIG. 9 illustrates another planar structural schematic of a display panel according to various embodiments of the present disclosure.

FIG. 10 illustrates another planar structural schematic of a display panel according to various embodiments of the present disclosure.

FIG. 11 illustrates another cross-sectional view along an A-A′ direction in FIG. 1.

FIG. 12 illustrates another cross-sectional view along an A-A′ direction in FIG. 1.

FIG. 13 illustrates another cross-sectional view along an A-A′ direction in FIG. 1.

FIG. 14 illustrates another cross-sectional view along an A-A′ direction in FIG. 1.

FIG. 15 illustrates another cross-sectional view along an A-A′ direction in FIG. 1.

FIG. 16 illustrates another cross-sectional view along an A-A′ direction in FIG. 1.

FIG. 17 illustrates another planar structural schematic of a display panel according to various embodiments of the present disclosure.

FIG. 18 illustrates another planar structural schematic of a display panel according to various embodiments of the present disclosure.

FIG. 19 illustrates a cross-sectional view along a B-B′ direction in FIG. 17.

FIG. 20 illustrates another cross-sectional view along an A-A′ direction in FIG. 1.

FIG. 21 illustrates another cross-sectional view along an A-A′ direction in FIG. 1.

FIG. 22 illustrates another cross-sectional view along an A-A′ direction in FIG. 1.

FIG. 23 illustrates another cross-sectional view along an A-A′ direction in FIG. 1.

FIG. 24 illustrates another planar structural schematic of a display panel according to various embodiments of the present disclosure.

FIG. 25 illustrates a schematic of a pixel circuit according to various embodiments of the present disclosure.

FIG. 26 illustrates a flowchart of a formation method of a display panel according to various embodiments of the present disclosure.

FIG. 27 illustrates another flowchart of a formation method of a display panel according to various embodiments of the present disclosure.

FIG. 28 illustrates another flowchart of a formation method of a display panel according to various embodiments of the present disclosure.

FIG. 29 illustrates another flowchart of a formation method of a display panel according to various embodiments of the present disclosure.

FIG. 30 illustrates a structural schematic of a display apparatus according to various embodiments of the present disclosure.

### DETAILED DESCRIPTION

Various exemplary embodiments of the present disclosure are described in detail with reference to accompanying drawings. It should be noted that unless stated otherwise, relative arrangement of assemblies and steps, numerical expressions and values described in those embodiments may not limit the scope of the present disclosure.

Following description of at least one exemplary embodiment may be merely illustrative and may not be configured to limit the present disclosure and its application or use.

The technologies, methods and apparatuses known to those skilled in the art may not be discussed in detail, but where appropriate, the technologies, methods and apparatuses should be considered as a part of the present disclosure.

In all examples shown and discussed herein, any specific value should be interpreted as merely exemplary, rather than as a limitation. Therefore, other examples in exemplary embodiment may have different values.

It should be noted that similar reference numerals and letters are configured to indicate similar items in following drawings. Therefore, once an item is defined in one drawing, it does not need to be further discussed in subsequent drawings.

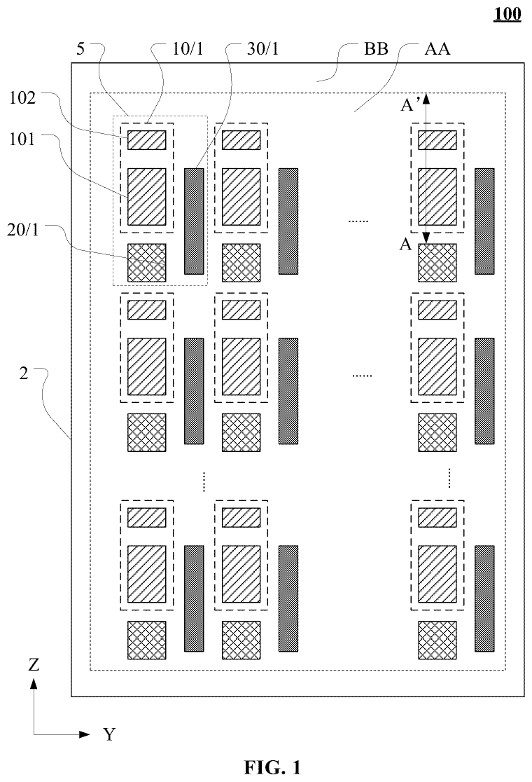

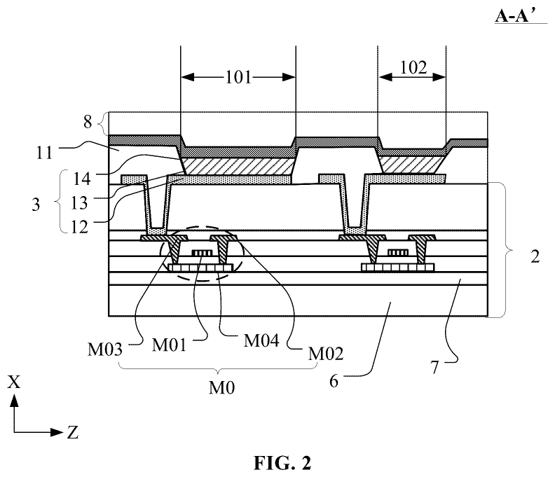

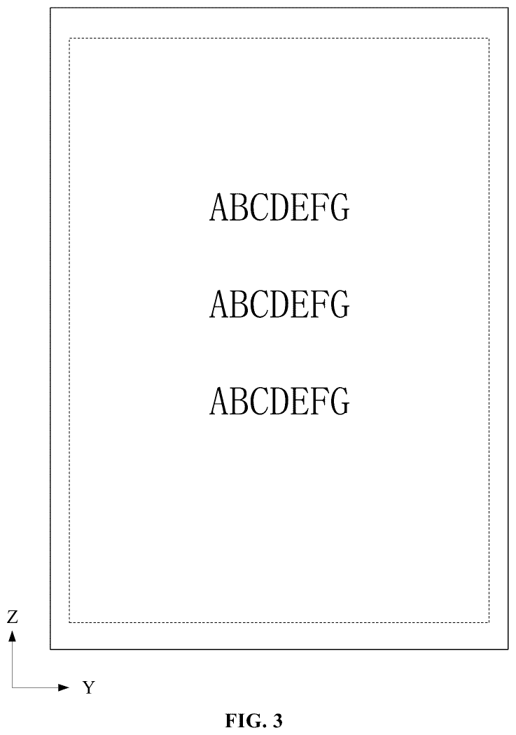

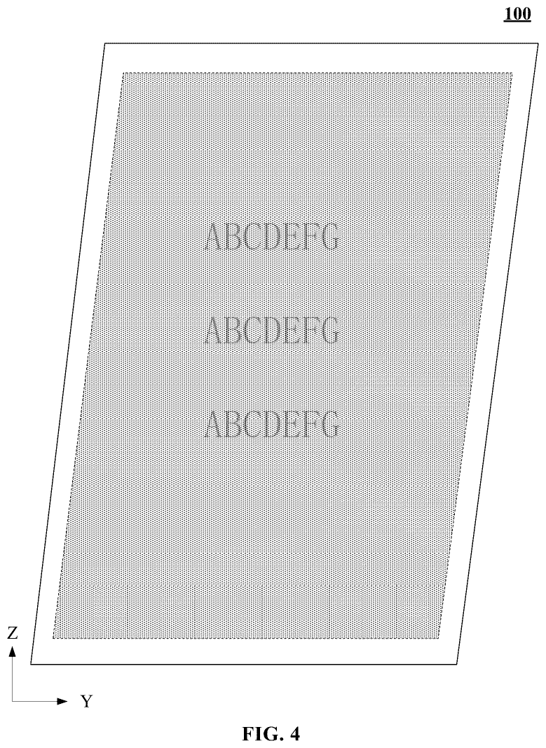

Referring to FIGS. 1-4, FIG. 1 illustrates a planar structural schematic of a display panel according to various embodiments of the present disclosure; FIG. 2 illustrates a cross-sectional view along an A-A′ direction in FIG. 1; FIG. 3 illustrates a schematic of a display panel displaying images in a display mode according to various embodiments of the present disclosure; and FIG. 4 illustrates a schematic of a display panel displaying images in an the anti-peep mode according to various embodiments of the present disclosure. A display panel 100 in one embodiment may include a plurality of sub-pixels 1, where the sub-pixel 1 may include a first sub-pixel 10, a second sub-pixel 20 and a third sub-pixel 30 which emit light with different colors; and the sub-pixel 1 may include a substrate 2, a light-emitting structure 3 on a side of the substrate 2, and an encapsulation layer 8 on a side of the light-emitting structure 3 away from the substrate 2.

At least the first sub-pixel 10 may include a first main sub-pixel 101 and a first interference sub-pixel 102, where the first interference sub-pixel 102 may at least partially surround the first main sub-pixel 101.

The display panel 100 may further include a display mode and an anti-peep mode during operation. In the display mode, the first main sub-pixel 101 may emit light, and the first interference sub-pixel 102 may not emit light. In the anti-peep mode, both the first main sub-pixel 101 and the first interference sub-pixel 102 may emit light, and the light emitted from the first interference sub-pixel 102 may emit light with a wide viewing angle from a light-exiting surface, where the angle between the large viewing angle and a first direction X may be greater than or equal to 30°, and the first direction X may be a direction perpendicular to the plane of the substrate.

For example, the display panel of the present disclosure may be an organic light-emitting display module. Referring to FIG. 1, the display panel in FIG. 1 may include a display region AA and a non-display region BB surrounding the display region AA. FIG. 1 only shows the situation where the non-display region BB completely surrounds the display region AA. Obviously, the non-display region BB may also partially surround the display region AA, as shown in a water drop screen, which may not be limited herein. The non-display region BB may include an upper frame and a lower frame arranged oppositely along a third direction Z. A driver chip (not shown in FIG. 1) may be bound to the lower frame, or the lower frame may be directly bent to the back of the display panel (the side away from the light-exiting surface), and the flexible circuit board and the driver chip may be bound after bending. Optionally, the display panel 100 may also include data lines arranged along a row direction and extending along a column direction, and also include scan lines extending along the row direction and arranged along the column direction. The scan lines and the data lines are not shown in FIGS. 1-4. The scan lines and the data lines may be arranged on the substrate 2. The driver chip may provide a data voltage to the data line and write the data voltage into the driver circuit in the substrate 2 through transmission of the data line. The structure of the pixel circuit may not be limited herein. Optionally, the pixel circuit may be a 7TIC circuit, an 8TIC circuit, or a 16TIC circuit, where T refers to a transistor and C refers to a storage capacitor.

Referring to FIG. 2, FIG. 2 illustrates that the substrate 2 may include a base substrate 6 and a drive transistor M0 on the side of the base substrate 6 adjacent to the light-exiting surface of the display panel. The drive transistor M0 may include a gate electrode M01, a source electrode M02 and a drain electrode M03. The substrate 2 may include the base substrate 6, an active layer M04, a first metal layer and a second metal layer which are arranged along the direction perpendicular to the display panel. The first metal layer and the second metal layer may not be labeled in FIG. 2. The drive transistor M0 may include the gate electrode M01 on the first metal layer and include the source electrode M02 and the drain electrode M03 on the second metal layer. An insulating layer 7 may be between the first metal layer and the second metal layer. In FIG. 2, pattern filling is not performed on the base substrate 6 and the insulating layer 7. Optionally, the data lines may be at a same layer as the second metal layer, and the scan lines may be at a same layer as the first metal layer. As shown in FIG. 2, a pixel defining layer 11 may be between any adjacent light-emitting structures 3, and each sub-pixel 1 may include the light-emitting structure 3. Obviously, the first main sub-pixel 101 may include the light-emitting structure 3, and the first interference sub-pixel 102 may also include the light-emitting structure 3. The light-emitting colors of the light-emitting structures 3 in the first main sub-pixel 101 and the first interference sub-pixel 102 may be same. The light-emitting structure 3 may include an anode 12 and a cathode 14, and a light-emitting layer 13 between the anode 12 and the cathode 14. Optionally, the light-emitting layer 13 may include a hole injection layer, a hole transport layer, a light-emitting material, a hole blocking layer, and an electron transport layer (not shown in FIG. 2) which are arranged sequentially along the direction from the substrate 2 to the light-emitting structure 3.

The anode 12 may be made of a variety of conductive materials. For example, the anode 12 may be a transparent electrode or a reflective electrode depending on the applications. When the anode 12 is a transparent electrode, the anode 12 may include indium tin oxide, indium zinc oxide, zinc oxide, indium oxide or the like.

The pixel defining layer 11 may be made of an organic material such as polyimide, polyamide, benzocyclobutene, acrylic resin, phenolic resin or the like. Pattern filling is not performed on the pixel defining layer 11 in FIG. 2.

The light-emitting layer 13 may be on the anode 12, and the portion of the anode 12 on which the light-emitting layer 13 is disposed may be not covered by the pixel defining layer 11 to be exposed. The light-emitting layer 13 may be formed by a vapor deposition process. The light-emitting layer 13 may be patterned to correspond to each sub-pixel 1, that is, to correspond to the patterned anode 12. The light-emitting layer 13 may be made of a low molecular weight organic material or a high molecular weight organic material.

The cathode 1 on the light-emitting layer 1 may be similar to the anode 12. The cathode 14 may be formed as a transparent electrode or a reflective electrode. It may be understood that the light-emitting layer 13 may include the hole injection layer disposed on the substrate 2, the hole transport layer disposed on the hole injection layer, the light-emitting layer 13 disposed on the hole transport layer, the hole blocking layer disposed on the light-emitting layer, and the electron transport layer disposed on the hole blocking layer. These film layers may be formed by a deposition manner. The light-emitting principle of the organic self-light-emitting display module is that organic light-emitting materials emit light through carrier injection and recombination when driven by an electric field. For example, an indium tin oxide (ITO) electrode and a metal electrode may be configured as the anode 12 and cathode 14 of the apparatus, respectively. Driven by a certain voltage, electrons and holes may be injected from the cathode 14 and the anode 12 into the electron transport layer and the hole transport layer respectively; electrons and holes may migrate to the organic light-emitting layer 13 through the electron transport layer and hole transport layer respectively, and meet in the organic light-emitting layer 13 to form excitons and excite the light-emitting molecules; and excited light-emitting molecules may undergo radiative relaxation to emit visible light.

It may be understood that the light-emitting layer 13 may be made of an organic material, which may cause the light-emitting structure 3 to fail when being exposed to water and oxygen. Therefore, the light-emitting structure 3 may be encapsulated through the encapsulation layer 8 to isolate the light-emitting structure 3 from water and oxygen.

For example, the encapsulation layer 8 may be on the side of the cathode 14 away from the substrate 2 to prevent water and oxygen from entering. Optionally, the encapsulation layer 8 may be a stacked structure of an inorganic encapsulation layer, an organic encapsulation layer and an inorganic encapsulation layer. Obviously, the structure of the encapsulation layer may not be limited in the present disclosure. The encapsulation layer may include multiple inorganic encapsulation layers and multiple organic encapsulation layers to form desirable protection for the light-emitting structure 3 in the display region. Obviously, FIG. 2 only illustrates approximate position of the encapsulation layer 8, which may not be used as actual film layer structure of the encapsulation layer.

Optionally, the first main sub-pixel 101 and the second interference sub-pixel 202 may be driven by the drive transistor M0 respectively. Therefore, when the first main sub-pixel 101 emits light, the first interference sub-pixel 102 may or may not emit light. For example, in the display mode, the first main sub-pixel 101 may emit light and the first interference sub-pixel 102 may not emit light; and in the anti-peep mode, the first main sub-pixel 101 may emit light, and the first interference sub-pixel 102 may also emit light. The first main sub-pixel 101 and the first interference sub-pixel 102 in FIGS. 1-2 may be both at a position of an opening region.

The sub-pixel 1 in the display panel of the present disclosure may include the first sub-pixel 10, the second sub-pixel 20 and the third sub-pixel 30. The first sub-pixel 10, the second sub-pixel 20 and the third sub-pixel 30 may emit light of different colors. The sub-pixel 1 may include the substrate 2, the light-emitting structure 3 on the side of the substrate 2, and the encapsulation layer 8 on the side of the light-emitting structure 3 away from the substrate 2. At least the first sub-pixel 10 may include the first main sub-pixel 101 and the first interference sub-pixel 102; and the first interference sub-pixel 102 may at least partially surround the first main sub-pixel 101. Obviously, the content shown in FIG. 3 is only a schematic illustration. As shown in FIG. 3, in the display mode, the first main sub-pixel 101 may emit light, and the first interference sub-pixel 102 may not emit light, such that the first sub-pixel 10 in the display mode may be displayed normally. As shown in FIG. 4, in the anti-peep mode, both the first main sub-pixel 101 and the first interference sub-pixel 102 may emit light, where the light emitted from the first interference sub-pixel 102 may emit light with the large viewing angle from the light-exiting surface, the angle between the large viewing angle and the first direction X may be greater than or equal to 30°, and the first direction X may be direction perpendicular to the plane of the substrate 2. In such way, the light of the first interference sub-pixel 102 may appear at a large viewing angle, such that the light of the first interference sub-pixel 102 may appear in the picture at the large viewing angle, and the content displayed on the display panel may be weakened, which may cause interference and anti-peep effect.

In some optional embodiments, referring to FIGS. 1-2, the area of the first interference sub-pixel 102 is S1, the area of the first main sub-pixel 101 is S2, and S1≤½×S2.

It may be understood that in the display mode, the first main sub-pixel 101 may emit light and the first interference sub-pixel 102 may not emit light. In order not to affect normal display of the display panel, the area of the first interference sub-pixel 102 cannot be excessively large. If the area of the first interference sub-pixel 102 is excessively large, the area of the first main sub-pixel 101 may be correspondingly reduced, which may affect normal display of the display panel in the display mode. Therefore, the area of the first interference sub-pixel 102 should be reduced as possible.

In one embodiment, the area S1 of the first interference sub-pixel 102 is not greater than ½ of the region S2 of the first main sub-pixel 101, for example, S1=⅕×S2, S1=¼×S2, S1=⅓×S2 or S1=½×S2, such that the impact on normal display of the display panel may be reduced.

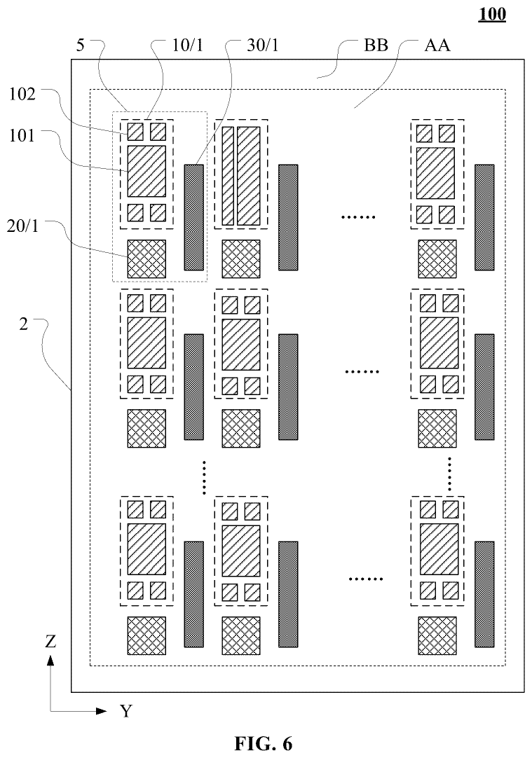

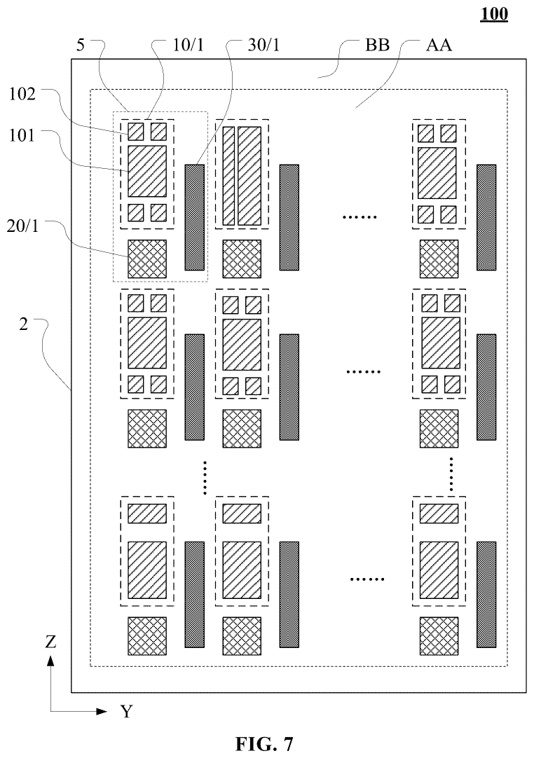

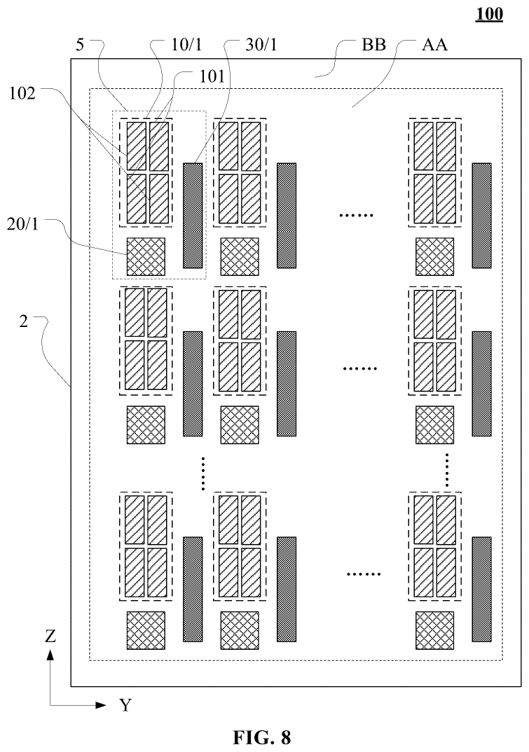

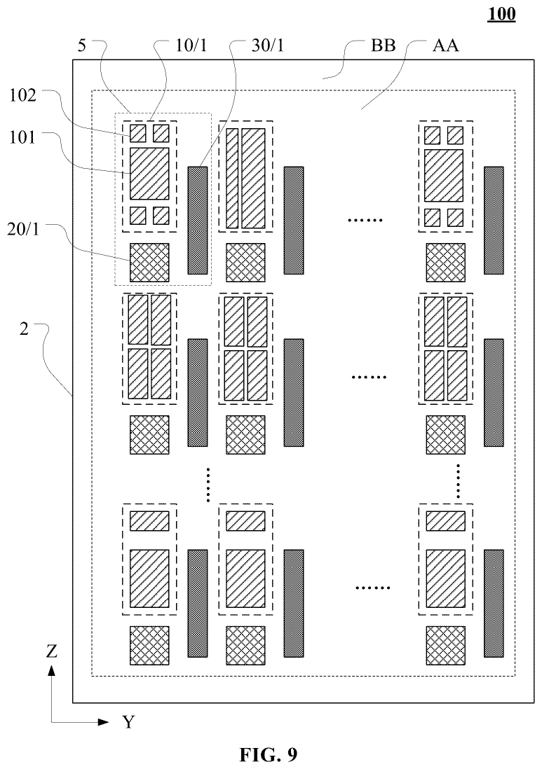

In some optional embodiments, referring to FIGS. 1, 5, and 7-9, FIG. 5 illustrates another planar structural schematic of a display panel according to various embodiments of the present disclosure; FIG. 6 illustrates another planar structural schematic of a display panel according to various embodiments of the present disclosure; FIG. 7 illustrates another planar structural schematic of a display panel according to various embodiments of the present disclosure; FIG. 8 illustrates another planar structural schematic of a display panel according to various embodiments of the present disclosure; and FIG. 9 illustrates another planar structural schematic of a display panel according to various embodiments of the present disclosure. In one embodiment, at least a part of the first interference sub-pixels 102 and a part of the first main sub-pixels 101 may be arranged along the second direction Y or the third direction Z, where the second direction Y may be the row direction, the third direction Z may be the column direction, and the second direction Y may intersect the third direction Z; and/or at least a part of the orthographic projections of the first interference sub-pixels 102 on the plane of the substrate 2 may surround the orthographic projection of the first main sub-pixel 101 on the plane of the substrate 2; and/or at least a part of the first interference sub-pixel 102 and the first main sub-pixel 101 may be arranged at vertex corners.

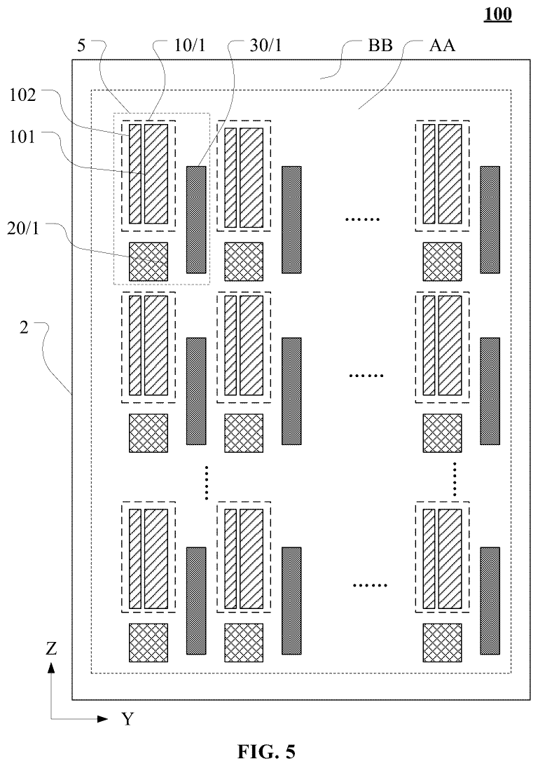

In FIG. 1, the first interference sub-pixel 102 and the first main sub-pixel 101 may be arranged along the third direction Z, where the third direction Z may be the column direction. In FIG. 5, the first interference sub-pixel 102 and the first main sub-pixel 101 may be arranged along the second direction Y, where the second direction Y may be the row direction. In FIG. 6, the orthographic projections of the first interference sub-pixels 102 on the plane of the substrate 2 may surround the orthographic projection of the first main sub-pixel 101 on the plane of the substrate 2. Obviously, the manner that the orthographic projections of the first interference sub-pixels 102 on the plane of the substrate 2 surrounds the orthographic projection of the first main sub-pixel 101 on the plane of the substrate 2 may be exemplary, and other surrounding manners may also be available, which may not be limited herein. In FIG. 7, a part of the first interference sub-pixels 102 and a part of the first main sub-pixels 101 may be arranged along the third direction Z; and the orthographic projections of a part of the first interference sub-pixels 102 on the plane of the substrate 2 may surround the orthographic projection of the first main sub-pixel 101 on the plane of the substrate 2. In FIG. 8, the first interference sub-pixels 102 and the first main sub-pixels 101 may be arranged at vertex corners. In FIG. 8, the first interference sub-pixels 102 may be arranged at the vertex corners, and the first main sub-pixels 101 may be arranged at vertex corners. For such arrangement, when the display panel is viewed from all viewing angles, the sub-pixels may be arranged symmetrically, and visual consistency may be obtained from different viewing angles. In FIG. 9, a part of the first interference sub-pixels 102 and a part of the first main sub-pixels 101 may be arranged along the third direction Z; the orthographic projections of a part of the first interference sub-pixels 102 on the plane of the substrate 2 may surround the orthographic projection of the first main sub-pixel 101 on the plane of the substrate 2; and a part of the first interference sub-pixels 102 and a part of the first main sub-pixels 101 may be arranged at vertex corners. Obviously, the arrangement of the first interference sub-pixels 102 and the first main sub-pixel 101s in the present disclosure may refer to a combination of any of above-mentioned embodiments, which may not be limited herein.

On the one hand, in one embodiment, by disposing the first interference sub-pixel 102 and the first main sub-pixel 101, in the anti-peep mode, the first main sub-pixel 101 and the first interference sub-pixel 102 may both emit light, the light emitted from the first interference sub-pixel 102 may emit light with a large viewing angle from the light-exiting surface, and the angle between the large viewing angle and the first direction X may be greater than or equal to 30°. In such way, the emitted light of the first interference sub-pixel 102 may appear at a large viewing angle. Therefore, the emitted light of the first interference sub-pixel 102 may appear in the pictures with a large viewing angle, and the contents displayed on the display panel may be weakened, which may cause interference and achieve the anti-peep effect. On the other hand, the arrangement relationship between the first interference sub-pixels 102 and the first main sub-pixels 101 may refer to any embodiment of the present disclosure. The first interference sub-pixels 102 and the first main sub-pixels 101 may be arranged along the second direction Y or the third direction Z; the orthographic projections of the first interference sub-pixels 102 on the plane of the substrate 2 may surround the orthographic projection of the first main sub-pixel 101 on the plane of the substrate 2; and the first interference sub-pixels 102 and the first main sub-pixels 101 may be arranged at vertex corners, which may realize product diversification.

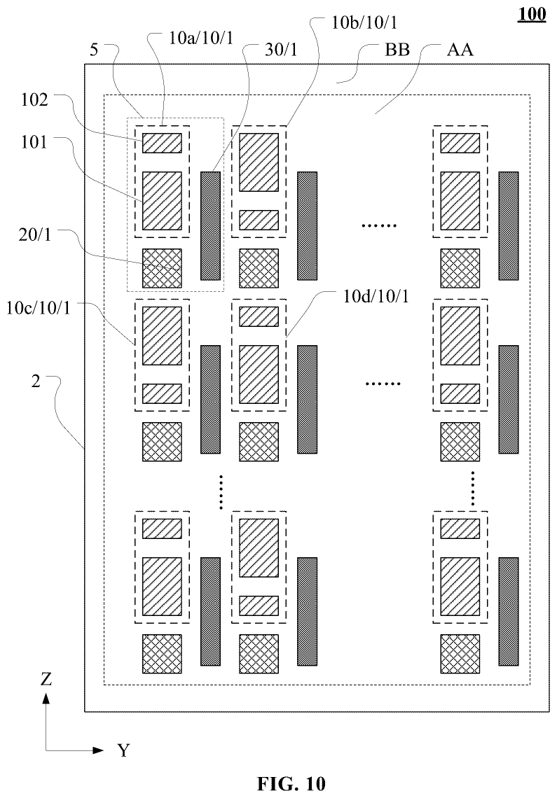

In some optional embodiments, referring to FIGS. 2 and 10, FIG. 10 illustrates another planar structural schematic of a display panel according to various embodiments of the present disclosure. Along the second direction Y, in two adjacent first sub-pixels 10, the first main sub-pixel 101 of one of two adjacent first sub-pixels 10 may be adjacent to the first interference sub-pixel 102 in another adjacent first sub-pixel 10 along the second direction Y; and along the third direction Z, in two adjacent first sub-pixels 10, the first main sub-pixel 101 of one of two adjacent first sub-pixels 10 may be adjacent to the first main sub-pixel 101 of another adjacent first sub-pixel 10 along the third direction Z, and the first interference sub-pixel 102 of one of two adjacent first sub-pixels 10 may be adjacent to the first interference sub-pixel 102 of another adjacent first sub-pixel 10 along the third direction Z.

The second direction Y may be the row direction, the third direction Z may be the column direction, and the second direction Y may intersect the third direction Z.

In FIG. 10, the first sub-pixel 10a and the first sub-pixel 10b may be at the first pixel row; and the second sub-pixel 20c and the first sub-pixel 10d may be at the second pixel row. Along the second direction Y, the first sub-pixel 10a may be adjacent to the first sub-pixel 10b, and the first sub-pixel 10c may be adjacent to the first sub-pixel 10d. Along the third direction Z, the first sub-pixel 10a may be adjacent to the first sub-pixel 10c, and the first sub-pixel 10b may be adjacent to the first sub-pixel 10d. Along the second direction Y, the first interference sub-pixel 102 in the first sub-pixel 10a may be adjacent to the first main sub-pixel 101 in the first sub-pixel 10b, the first main interference sub-pixel 1 in the first sub-pixel 10a may be adjacent to the first interference sub-pixel 102 in the first sub-pixel 10b, the first main sub-pixel 101 in the first sub-pixel 10c may be adjacent to the first interference sub-pixel 102 in the first sub-pixel 10d, and the first interference sub-pixel 102 in the first sub-pixel 10c may be adjacent to the first main sub-pixel 101 in the first sub-pixel 10d. Along the third direction Z, the first main sub-pixel 101 in the first sub-pixel 10a may be adjacent to the first main sub-pixel 101 in the first sub-pixel 10c, and the first interference sub-pixel 102 in the first sub-pixel 10b may be adjacent to the first interference sub-pixel 102 in the first sub-pixel 10d. It should be noted that adjacency herein refers to corresponding arrangement relationship. That is, the first interference sub-pixel 102 and the first main sub-pixel 101 in the first sub-pixel 10a may be arranged along the third direction Z, the first main sub-pixel 101 and the first interference sub-pixel 102 in the first sub-pixel 10b may be arranged along the third direction Z, the first main sub-pixel 101 and the first interference sub-pixel 102 in the first sub-pixel 10c may be arranged along the third direction Z, and the first interference sub-pixel 102 and the first main sub-pixel 101 in the first sub-pixel 10d may be arranged along the third direction Z.

It may be understood that in one embodiment, in two adjacent first sub-pixels 10 along the second direction Y and the third direction Z, both the first interference sub-pixels 102 and the first main sub-pixels 101 may be arranged asymmetrically. Referring to FIG. 2, it may be understood that when the first interference sub-pixel 102 and the first main sub-pixel 101 are formed, the light-emitting layer 13 may need to be formed in the opening of the pixel defining layer 11. Since the first interference sub-pixel 102 and the first main sub-pixel 101 are both in the first sub-pixel 10, the distance between the first interference sub-pixel 102 and the first main sub-pixel 101 may be relatively close to each other. Therefore, the opening of the pixel defining layer 11 between the first interference sub-pixel 102 and the first main sub-pixel 101 may be also relatively small. Due to the limitation of the formation process, the inclination angle K1 of the pixel defining layer 11 between the first interference sub-pixel 102 and the first main sub-pixel 101 may be different from the inclination angle K2 between other sub-pixels 1. Therefore, the angle of the light-emitting layer 13 formed at the opening of the pixel defining layer 11 may be also different; and finally, the light-emitting angle of the first interference sub-pixel 102 may be also different, which may affect brightness attenuation under the large viewing angle and result in differences in visual effect. In one embodiment, in two adjacent first sub-pixels 10 along the second direction Y, the first main sub-pixel 101 of one of two adjacent first sub-pixels 10 may be adjacent to the first interference sub-pixel 102 in another adjacent first sub-pixel 10 along the second direction Y. Along the third direction Z, in two adjacent first sub-pixels 10, the first main sub-pixel 101 of one of two adjacent first sub-pixels 10 may be adjacent to the first main sub-pixel 101 of another adjacent first sub-pixels 10 along the third direction Z; and the first interference sub-pixel 102 of one of two adjacent first sub-pixels 10 may be adjacent to the first interference sub-pixel 102 of another adjacent first sub-pixel 10 along the third direction Z. Along the second direction Y and the third direction Z, in two adjacent first sub-pixels 10, the first interference sub-pixel 102 and the first main sub-pixel 101 may be arranged asymmetrically. Certain process differences may be in both the second direction Y and the third direction Z, which may avoid that the visual effect is affected by the process difference only along the second direction Y or the third direction Z, thereby compensating the visual effect difference caused by the process difference.

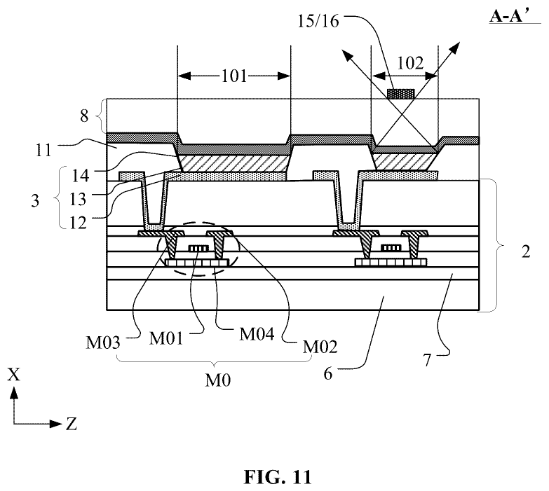

In some optional embodiments, referring to FIG. 11, FIG. 11 illustrates another cross-sectional view along the A-A′ direction in FIG. 1. In the first interference sub-pixel 102 in FIG. 11, the side of the encapsulation layer 8 away from the light-emitting structure 3 may include a light guide structure 15; the orthographic projection of the light guide structure 15 on the plane of the substrate 2 and the orthographic projection of the light-emitting structure 3 on the plane of the substrate 2 may be at least partially overlapped with each other; and the light guide structure 15 may include a light-blocking layer 16.

For example, the light guide structure 15 may be on the side of the encapsulation layer 8 away from the substrate 2. In some optional embodiments, a touch-control layer (not shown in drawings) may be also included on the side of the encapsulation layer 8 away from the substrate 2, and the light guide structure 15 may be on the side of the touch-control layer away from the encapsulation layer 8. In FIG. 11, the orthographic projection of the light guide structure 15 on the plane of the substrate 2 may be partially overlapped with the orthographic projection of the light-emitting structure 3 on the plane of the substrate 2. More precisely, the orthographic projection of the light guide structure 15 on the plane of the substrate 2 may be within the orthographic projection of the light-emitting structure 3 on the plane of the substrate 2. Obviously, the encapsulation layer 8 has a certain thickness, such that even if the orthographic projection of the light guide structure 15 on the plane of the substrate 2 is overlapped with the orthographic projection of the light-emitting structure 3 on the plane of the substrate 2, the light may still be emitted along the outer edge of the light guide structure 15.

Optionally, the light guide structure 15 may be an opaque structure, for example, the light-blocking layer 16. Optionally, using a same material as the black matrix BM, the light emitted from the light-emitting layer 13 in the first interference sub-pixel 102 may not directly penetrate the light guide structure 15 after passing through the cathode 14 and the encapsulation layer 8, instead, may radiate along the outer edge of the light guide structure 15 toward the light-exiting surface. Therefore, in the anti-peep mode, the light emitted from the first interference sub-pixel 102 may be guided to the large viewing angle. In such way, the light of the first interference sub-pixel 102 may appear at the large viewing angle. Therefore, the light of the first interference sub-pixel 102 may appear in the pictures with the large viewing angle, and the contents displayed on the display panel may be weakened, which may cause interference and achieve the anti-peep effect.

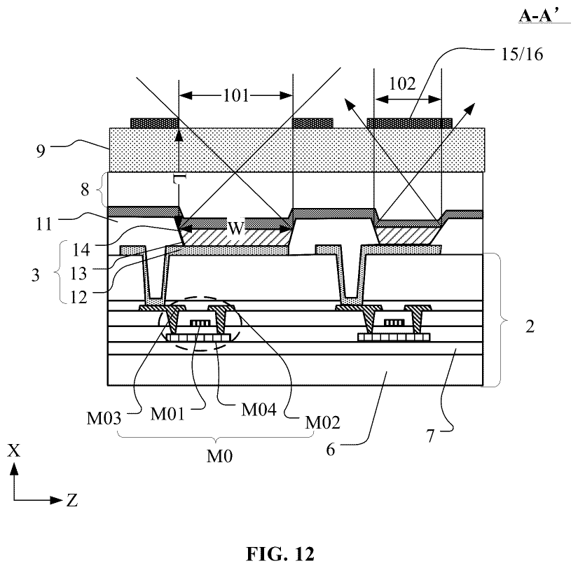

In some optional embodiments, referring to FIG. 12, FIG. 12 illustrates another cross-sectional view along the A-A′ direction in FIG. 1. In the first main sub-pixel 101, along the first direction X, the maximum distance between the light guide structure 15 and the light-emitting structure 3 is L, and the width of the light-emitting structure 3 along the second direction Y or the third direction Z is W, where tan30°≤W/L≤tan45°, the second direction Y is the row direction, the third direction Z is the column direction, and the second direction Y intersects the third direction Z.

FIG. 12 illustrates that the side of the encapsulation layer 8 away from the substrate 2 may also include the touch-control layer 9 to implement the touch-control function. Since the touch-control layer 9 has a certain thickness, in order to guide the light emitted from the light-emitting layer 13 to a large viewing angle in the first interference sub-pixel 102, the region of the light guide structure 15 may need to be large. Optionally, in FIG. 12, the orthographic projection of the light-emitting layer 13 of the first interference sub-pixel 102 on the plane of the substrate 2 may be within the orthographic projection of the light guide structure 15 on the plane of the substrate 2. Even if the distance between the light-emitting layer 13 of the first interference sub-pixel 102 and the light-guiding structure 15 is relatively large along the first direction X, it ensures that the light emitted from the light-emitting layer 13 of the first interference sub-pixel 102 may be guided to the large viewing angle. In the anti-peep mode, the light of the first interference sub-pixel 102 may appear in the pictures at the large viewing angle, and the contents displayed on the display panel may be weakened, which may cause interference and achieve the anti-peep effect.

For example, in the anti-peep mode, the first main sub-pixel 101 should try not to emit light at the large viewing angle, that is, no light should be emitted when the angle with the first direction X is greater than 45°, which may ensure that the contents displayed by the first main sub-pixel 101 cannot be observed under the large viewing angle. Along the first direction X, the maximum distance between the light guide structure 15 and the light-emitting structure 3 is L. Herein L refers to the distance along the first direction X between the light-emitting layer 13 (the side adjacent to the light-exiting surface) and the side of the light guide structure 15 away from the substrate 2. The width of the light-emitting structure 3 along the second direction Y or the third direction Z is W. In FIG. 12, the width of the light-emitting structure 3 along the third direction Z is W used as an example for illustration. Obviously, the principle that the width of the light-emitting structure 3 along the second direction Y is W may be same as other embodiments.

Referring to FIG. 12, W/L cannot be excessively large or excessively small. If W/L is excessively large, for example, W/L>tan45°, the angle between the light-emitting of the first main sub-pixel 101 and the first direction X may be greater than 45°. Therefore, the first main sub-pixel 101 may emit light at the large viewing angle, which may be not beneficial for the anti-peep. If W/L is excessively small, for example, W/L<tan30°, the width of the light-emitting structure 3 along the second direction Y or the third direction Z is excessively small, and the distance from the light-blocking layer 16 may be relatively large. Therefore, the light-emitting structure 3 (light-blocking layer 16) may reduce the opening of the first main sub-pixel 101, which may result in that the amount of light emitted along the first direction X is reduced to affect the display function.

In one embodiment, tan30°≤W/L≤ tan45°, which may not reduce the opening of the first main sub-pixel 101 to affect the display function and may also prevent the first main sub-pixel 101 from emitting light at the large viewing angle, and further improving the anti-peep effect.

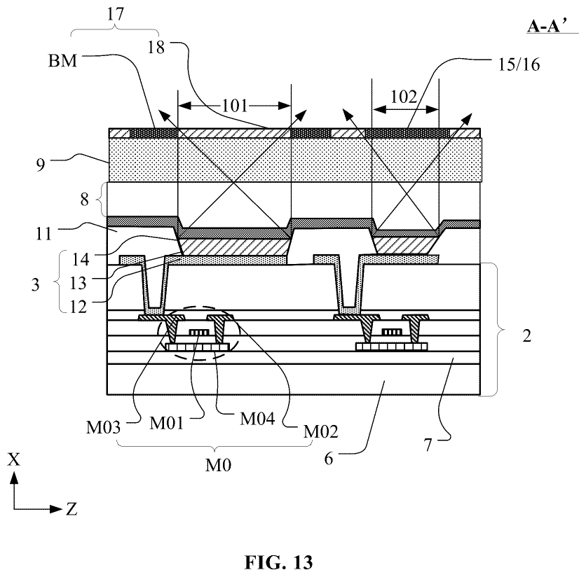

In some optional embodiments, referring to FIG. 13, FIG. 13 illustrates another cross-sectional view along the A-A′ direction in FIG. 1. The sub-pixel 1 may also include a color filter layer 17 on the side of the encapsulation layer 8 away from the substrate 2; the color filter layer 17 may include a black matrix BM and a color resist 18 in the opening of the black matrix BM; and the material of the light guide structure 15 may be same as the material of the black matrix BM.

It may be understood that organic self-light-emitting display panels need to be disposed with polarizers on the side of the light-exiting surface to prevent reflection; and after disposing the polarizers, the transmittance may be greatly reduced. In one embodiment, the color filter layer 17 may be disposed on the side of the encapsulation layer 8 away from the substrate 2, such that the polarizers may be not disposed. The color resist 18 corresponding to the light-emitting region of sub-pixel 1 may be disposed to achieve light filtering. The black matrix BM may be at the position corresponding to the gap of sub-pixel 1 to prevent reflection. In one embodiment, the material of the light guide structure 15 may be same as the material of the black matrix BM. The material of the light guide structure 15 may be easily obtained; and there is no need to provide other materials to form the light guide structure 15, which may reduce the production cost.

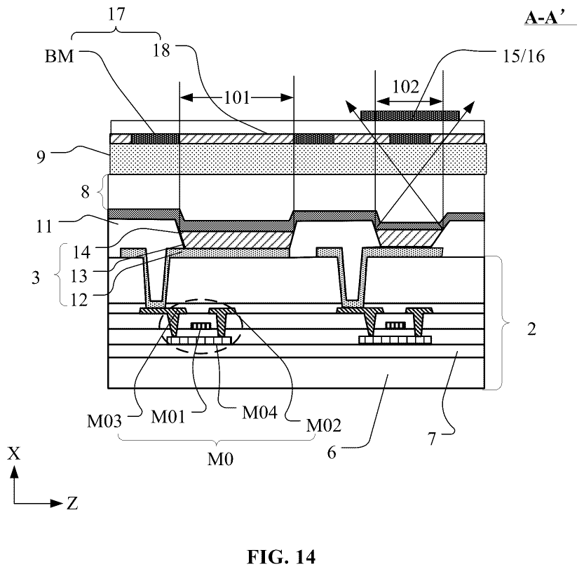

In some optional embodiments, referring to FIG. 14, FIG. 14 illustrates another cross-sectional view along the A-A′ direction in FIG. 1. The light guide structure 15 may be on the side of the black matrix BM away from the substrate 2.

It may be understood that a planarization layer may be disposed on the side of the black matrix BM away from the substrate 2, and the light guide structure 15 may be disposed on the side of the planarization layer away from the substrate 2. Obviously, the material of the light guide structure 15 may be same as or different from the material of the black matrix BM. The light guide structure 15 may be on the side of the black matrix BM away from the substrate 2. In such way, the distance between the light guide structure 15 and the light-emitting layer 13 along the first direction X may be not limited by the position of the color filter layer 17; and the distance between the light guide structure 15 and the light-emitting layer 13 along the first direction X may be adjusted according to actual needs, thereby changing and adjusting the light-emitting angle of the first interference sub-pixel 102.

In some optional embodiments, referring to FIG. 13, the black matrix BM may be reused as the light guide structure 15.

For example, the material used in the black matrix BM may be an opaque material. In FIG. 13, the black matrix BM may be used as the light guide structure 15. When forming the black matrix BM, the light guide structure 15 may be formed. The light emitted from the light-emitting layer 13 of the first interference sub-pixel 102 cannot pass through the black matrix BM but exit along the outer edge of the black matrix BM, which may simplify the formation process.

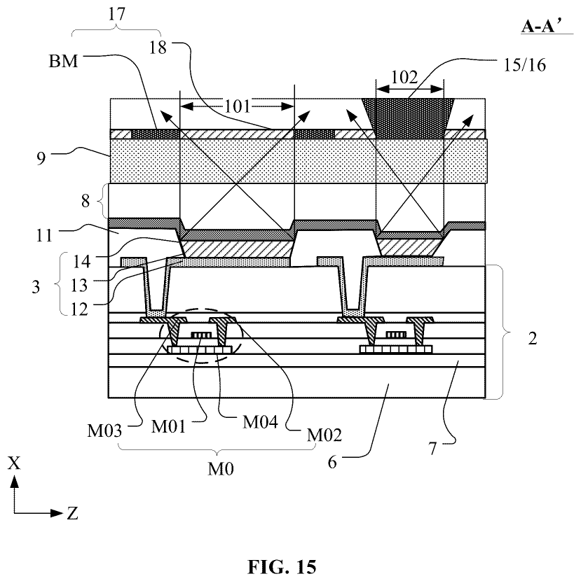

In some optional embodiments, referring to FIG. 15, FIG. 15 illustrates another cross-sectional view along the A-A′ direction in FIG. 1. The cross section of the light guide structure 15 may be an inverted trapezoid.

In one embodiment, the black matrix BM may be reused as the light guide structure 15, and the material used in the black matrix BM may be an opaque material. In FIG. 15, the black matrix BM may be used as the light guide structure 15. When forming the black matrix BM, the light guide structure 15 may be formed. The light emitted from the light-emitting layer 13 of the first interference sub-pixel 102 cannot pass through the black matrix BM but exit along the outer edge of the black matrix BM, which may simplify the formation process. In addition, in one embodiment, the cross section of the light guide structure 15 may be an inverted trapezoid. The height of the light guide structure 15 along the first direction X may be relatively large, such that the light guide structure 15 may be easily formed and may also guide the light to the large viewing angle as possible.

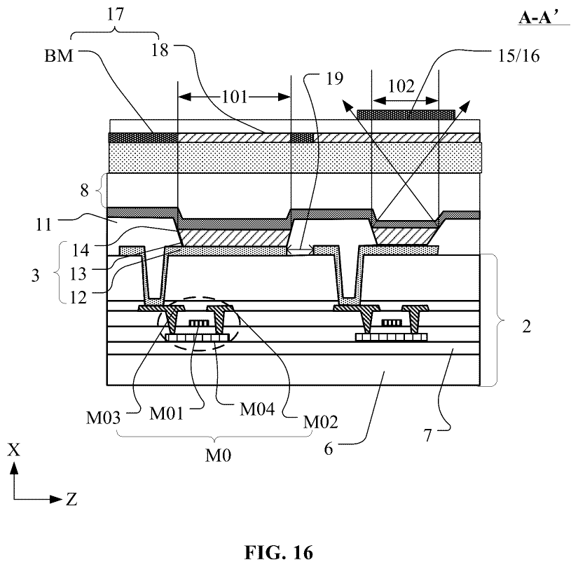

In some optional embodiments, referring to FIG. 16, FIG. 16 illustrates another cross-sectional view along the A-A′ direction in FIG. 1. The light-emitting structure 3 may also include the anode 12, the light-emitting layer 13 and the cathode 14 which are arranged sequentially along the plane perpendicular to the substrate 2; a groove 19 may be between the anode 12 of the first interference sub-pixel 102 and the anode 12 of the first main sub-pixel 101; and the orthographic projection of the groove 19 on the plane of the substrate 2 may be at least partially overlapped with the orthographic projection of the black matrix BM on the plane of the substrate 2.

It may be understood that the first interference sub-pixel 102 and the first main sub-pixel 101 may emit light independently, and the groove 19 may be disposed between the anode 12 of the first interference sub-pixel 102 and the anode 12 of the first main sub-pixel 101. Therefore, the first interference sub-pixel 102 and the second main sub-pixel 201 may be driven to emit light respectively. In addition, the function of black matrix BM may be to prevent light mixing. The light may not transmit the black matrix BM. The orthographic projection of the groove 19 on the plane of the substrate 2 and the orthographic projection of the black matrix BM on the plane of the substrate 2 may be at least partially overlapped with each other. In such way, the opening region of the first interference sub-pixel 102 blocked by the black matrix BM may be reduced, and the light-emitting amount of the first interference sub-pixel 102 may be increased. Obviously, the opening region of the first main sub-pixel 101 blocked by the black matrix BM may also be reduced, and the amount of light emitted from the first main sub-pixel 101 may be increased, which may improve the display performance.

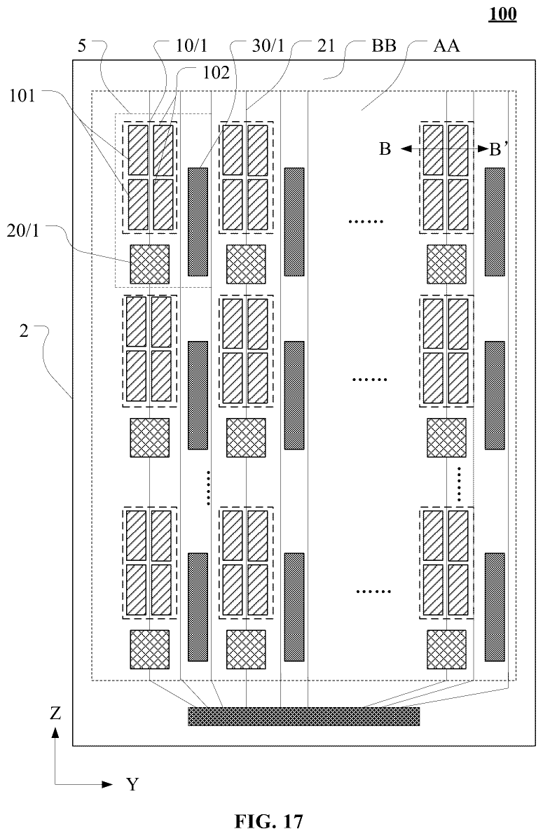

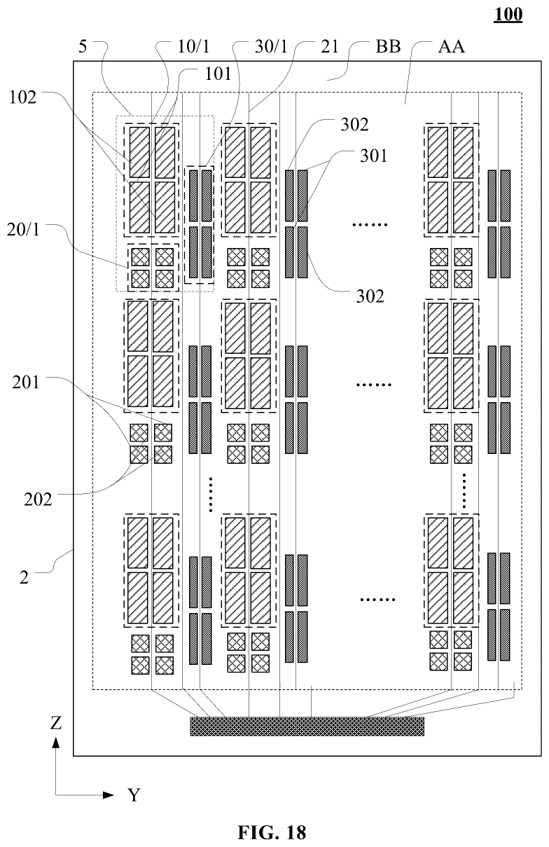

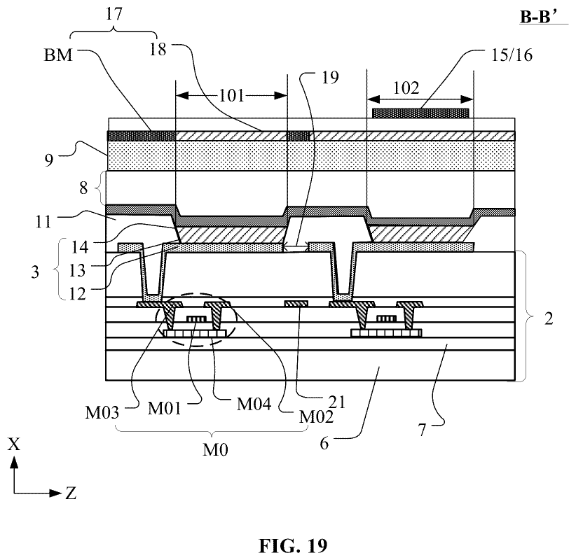

In some optional embodiments, referring to FIGS. 17-19, FIG. 17 illustrates another planar structural schematic of the display panel according to various embodiments of the present disclosure; FIG. 18 illustrates another planar structural schematic of the display panel according to various embodiments of the present disclosure; and FIG. 19 illustrates a cross-sectional view along a B-B′ direction in FIG. 17. In FIGS. 17-18, the substrate 2 may include a base substrate 6 and a data line 21 on the base substrate 6 adjacent to the light-emitting structure 3. The data line 21 may provide a data voltage to the sub-pixel 1. The orthographic projection of the data line 21 on the plane of the base substrate 6 may be within the orthographic projection of the groove 19 on the plane of the base substrate 6.

In FIGS. 17-18, the first interference sub-pixels 102 and the first main sub-pixels 101 may be arranged at vertex corners. Referring to FIG. 18, in one embodiment, the second sub-pixel 20 may include a second interference sub-pixel 202 and a second main sub-pixel 201 which are arranged at vertex corners; and the third sub-pixel 30 may include a third interference sub-pixel 302 and a third main sub-pixel 301 which are arranged at vertex corners. In the display mode, the first main sub-pixel 101 may emit light; the second main sub-pixel 201 and the third main sub-pixel 301 may emit light; and the first interference sub-pixel 102, the second interference sub-pixel 202, and the third interference sub-pixel 302 may not emit light. In such way, the first sub-pixel 10, the second sub-pixel 20, and the third sub-pixel 30 may display normally in the display mode. In the anti-peep mode, each of the first main sub-pixel 101 and the first interference sub-pixel 102 may emit light; each of the second main sub-pixel 201 and the second interference sub-pixel 202 may emit light; and each of the third main sub-pixel 301 and the third interference sub-pixel 302 may also emit light. The light emitted from the first interference sub-pixel 102, the second interference sub-pixel 202 and the third interference sub-pixel 302 may exit at the wide viewing angle from the light-exiting surface. The angle between the large viewing angle and the first direction X may be greater than or equal to 30°. The first direction X may be the direction perpendicular to the plane of the substrate 2. In such way, the light emitted from the first interference sub-pixel 102, the second interference sub-pixel 202 and the third interference sub-pixel 302 may appear at the large viewing angle. Therefore, the light emitted from the first interference sub-pixel 102, the second interference sub-pixel 202 and the third interference sub-pixel 302 may appear in the pictures at the large viewing angle, and the contents displayed on the display panel may be further weakened, which may cause interference and better realize the anti-peep effect. Obviously, in one embodiment of FIG. 18, the first interference sub-pixels 102 may be arranged at the vertex corners, the first main sub-pixels 101 may be arranged at the vertex corners, the second interference sub-pixels 202 may be arranged at the vertex corners, the second main sub-pixels 201 may be arranged at the vertex corners, the third interference sub-pixels 302 may be arranged at the vertex corners, and the third main sub-pixels 301 may be arranged at the vertex corners. The sub-pixels 1 of the display panel may be symmetrical from all angles, which may further improve the consistency of visual effect under different viewing angles.

It may be understood that the data line 21 may provide the data voltage for the sub-pixel 1, and the anode 12 may also need to be inputted with the drive voltage. When the data line 21 is overlapped with the anode 12 along the direction perpendicular to the plane of the substrate 2, coupling (i.e., data loading) may occur between the data voltage of the data line 21 and the anode 12, which may affect the display function. In one embodiment, the orthographic projection of the data line 21 on the plane of the substrate 6 may be within the orthographic projection of the groove 19 on the plane of the substrate 6. In such way, along the direction perpendicular to the plane of the substrate 2, the data line 21 may not be overlapped with the anode 12, and there is no coupling between the data line 21 and the anode 12, thereby improving the display performance.

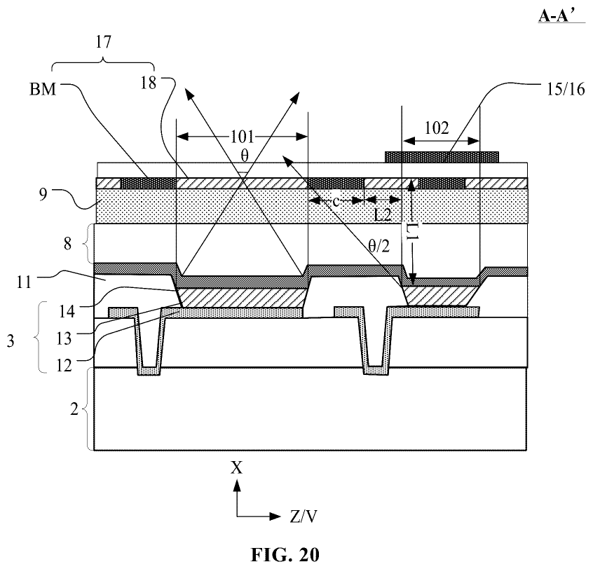

In some optional embodiments, referring to FIG. 20, FIG. 20 illustrates another cross-sectional view along the A-A′ direction in FIG. 1. In FIG. 20, some film layers are omitted, and only the light-emitting structure 3 and the film layers on the side of the light-emitting structure 3 away from the substrate 2 are shown. The maximum viewing angle of the first main sub-pixel 101 is 0; the width of the black matrix BM between the first main sub-pixel 101 and the first interference sub-pixel 102 along the fifth direction V is c; and in the first interference sub-pixel 102, along the first direction X, the maximum distance between the light guide structure 15 and the light-emitting structure 3 is L1; and L2 is a partial length of the color resist 18 between an end of the black matrix BM and an adjacent end of the light-emitting structure 2 along the fifth direction V, where tan(θ/2)=(L2+c)/L1, and the fifth direction V is the direction that the first main sub-pixel 101 points to the first interference sub-pixel 102.

It may be understood that during the anti-peep mode, the light emitted from the first interference sub-pixel 102 cannot affect normal display of the first main sub-pixel 101. That is, the light emitted from the first interference sub-pixel 102 cannot be guided into the visible region of the first main sub-pixel 101.

In one embodiment, the maximum light-emitting angle of the first interference sub-pixel 102 may be regarded as θ/2, that is, equal to half of the maximum viewing angle θ of the first main sub-pixel 101. According to the trigonometric function relationship, tan(θ/2)=(L2+c)/L1. At this point, through the black matrix BM between the first interference sub-pixel 102 and the first main sub-pixel 101, the light emitted from the first interference sub-pixel 102 may be blocked to prevent the light emitted from the first interference sub-pixel 102 from entering the viewing angle of the first main sub-pixel 101, which may avoid affecting normal display of the first sub-pixel 10 in the anti-peep mode.

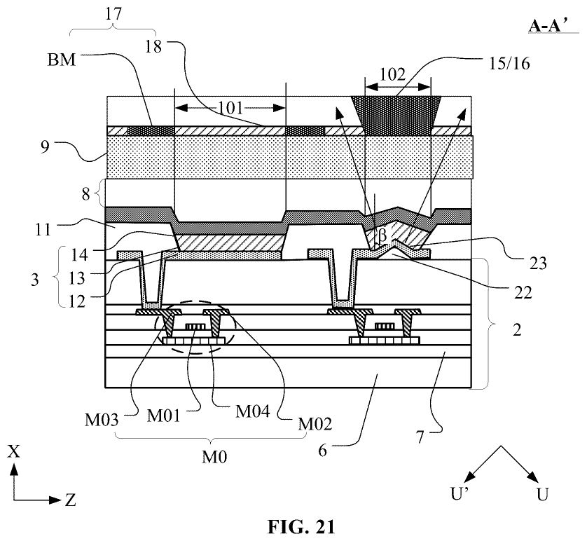

In some optional embodiments, referring to FIG. 21, FIG. 21 illustrates another cross-sectional view along the A-A′ direction in FIG. 1. In the first interference sub-pixel 102, the light-emitting structure 3 may also include the anode 12; the anode 12 may include an inclined surface 23 inclined along the fourth direction U/U′; the fourth direction U/U′ and the first direction X may have an included angle β; and β>0°.

It should be noted that the direction of the fourth direction U/U′ may not be limited, which may only need to satisfy that the light emitted from the first interference sub-pixel 102 may be diffused to the large viewing angle after the inclined surface of the anode 12 is tilted along the fourth direction U/U′.

As disclosed above, the light-emitting structure 3 of the sub-pixel 1 may include the anode 12, the light-emitting layer 13 on the side of the anode 12 away from the substrate 2, and the cathode 14 on the side of the light-emitting layer 13 away from the substrate 2. In one embodiment, the anode 12 corresponding to the first interference sub-pixel 102 may include the inclined surface 23. The inclined surface 23 may be inclined along the fourth direction U/U′. As shown in drawings, the fourth direction U/U′ and the first direction X may have the included angle β, and β>0°. The anode 12 may include the inclined surface 23. It may be understood that the light emitted from the first interference sub-pixel 102 may be perpendicular to the inclined surface 23 or have a certain angle with the inclined surface 23. Therefore, the inclined surface 23 may further guide the light of the first interference pixel to the large viewing angle, thereby enhancing the anti-peep effect.

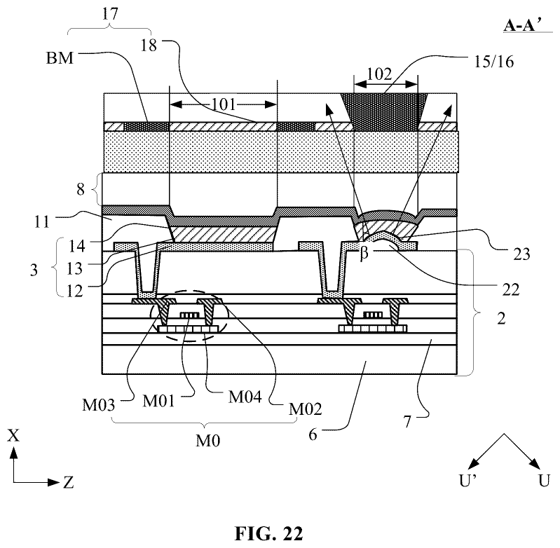

In some optional embodiments, referring to FIG. 22, FIG. 22 illustrates another cross-sectional view along the A-A′ direction in FIG. 1. The inclined surface 23 of the anode 12 may be an arc-shaped surface.

For example, the inclined surface 23 of the anode 12 may be an arc surface. The light emitted from the first interference sub-pixel 102 may be perpendicular to the inclined surface 23 or have a certain angle with the inclined surface 23. Therefore, the inclined surface 23 may further guide the light of the first interference pixel to the large viewing angle, thereby enhancing the anti-peep effect.

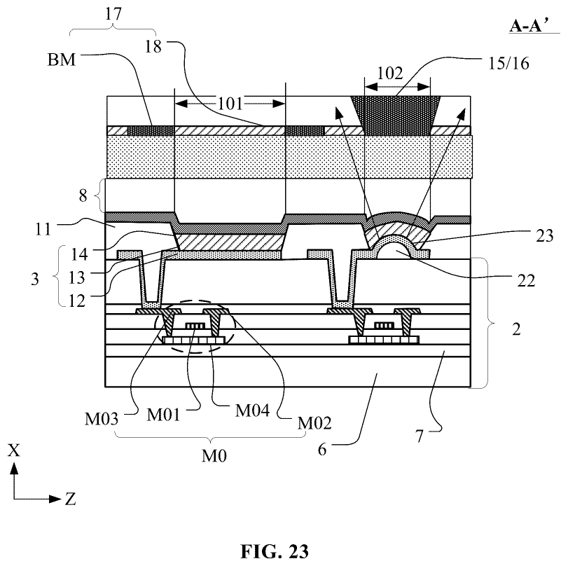

In some optional embodiments, referring to FIG. 23, FIG. 23 illustrates another cross-sectional view along the A-A′ direction in FIG. 1. The cross section of the anode 12 may be semicircular.

For example, the inclined surface 23 of the anode 12 may be semicircular. The light emitted from the first interference sub-pixel 102 may be perpendicular to the inclined surface 23 or have a certain angle with the inclined surface 23. Therefore, the inclined surface 23 may further guide the light of the first interference pixel to the large viewing angle to enhance the anti-peep effect.

In some optional embodiments, referring to FIGS. 21-23, the light-emitting structure 3 may further include a padding layer portion 22. The padding layer portion 22 may be on the side of the anode 12 adjacent to the substrate 2. The padding layer portion 22 may include an inclined surface inclined along the fourth direction U/U′. The anode 12 may cover a side of the inclined surface away from the substrate 2.

Corresponding to the first interference sub-pixel 102, the anode 12 may include the padding layer portion 22 on the side adjacent to the substrate 2. The padding layer portion 22 may include the inclined surface inclined along the fourth direction U/U′. Next, the anode 12 may be formed on the side of the padding layer portion 22 away from the substrate 2. The anode 12 may cover the side of the inclined surface away from the substrate 2, such that the inclined surface 23 inclined along the fourth direction U/U′ may be formed at the anode 12. The light emitted from the first interference sub-pixel 102 may be perpendicular to the inclined surface. Therefore, the inclined surface may further guide the light of the first interference pixel to the large viewing angle to enhance the anti-peep effect.

In some optional embodiments, referring to FIGS. 1-2, the color the light emitted from the first sub-pixel 10 may be green.

For example, the color the light emitted from the first interference sub-pixel 102 and the first main sub-pixel 101 may be green. It may be understood that the human eye is more sensitive to green light, and the green light is more easily observed by the human eye. Therefore, when in the anti-peep mode, the first interference sub-pixel 102 may emit the green light. The green light emitted from the first interference sub-pixel 102 may exit at the wide viewing angle from the light exit surface. In such way, the green light easily recognized by the human eye may appear at the large viewing angle. What the human eye observes is blurry green light, and the contents displayed on the display panel may become blurry at the large viewing angle, which may cause interference and achieve the anti-peep effect.

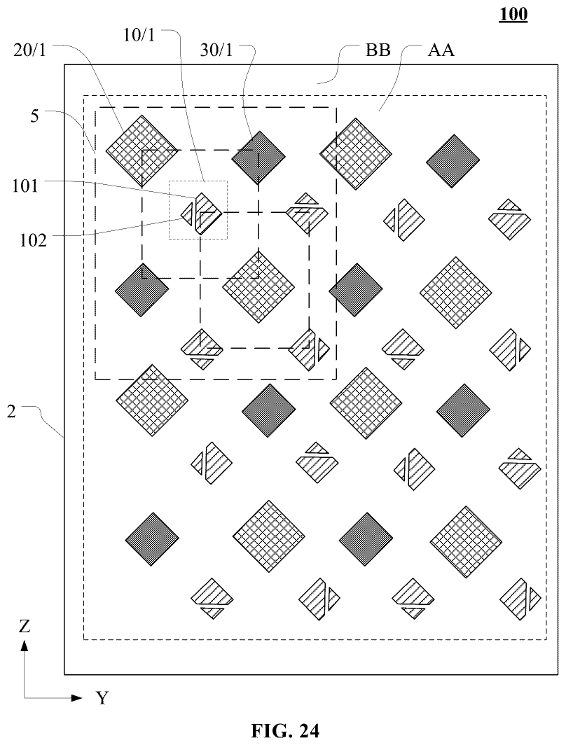

In some optional embodiments, referring to FIG. 24, FIG. 24 illustrates another planar structural schematic of the display panel according to various embodiments of the present disclosure. The display panel may include a plurality of pixel repeating units 5 arranged in a matrix. The pixel repeating unit may include two second sub-pixels 20, two third sub-pixels 30 and four first sub-pixels 10.

In a same pixel repeating unit 5, two second sub-pixels 20 and two third sub-pixels 30 may be arranged in two rows and two columns; and two sub-pixels 1 arranged in a same row or same column may emit different colors.

The centers of two second sub-pixels 20 and the centers of two third sub-pixels 30 may form a first virtual quadrilateral, and the first sub-pixel 10 may be inside the first virtual quadrilateral.

The geometric centers of four first sub-pixels 10 may form a second virtual quadrilateral; and the second sub-pixel 20 or the third sub-pixel 30 may be inside the second virtual quadrilateral.

In FIG. 24, the first sub-pixel 10, the second sub-pixel 20 and the third sub-pixel 30 may be arranged in a diamond arrangement. Such arrangement may make the distance between the sub-pixels 1 smaller to effectively improve equivalent resolution. The first sub-pixels 10 may include the first interference sub-pixel 102 and the first main sub-pixel 101. In the display mode, the first main sub-pixel 101 may emit light, and the first interference sub-pixel 102 may not emit light, such that the first sub-pixel 10 may display normally in the display mode. In the anti-peep mode, both the first main sub-pixel 101 and the first interference sub-pixel 102 may emit light. The light emitted from the first interference sub-pixel 102 may emit light with the large viewing angle from the light-exiting surface. The angle between the large viewing angle and the first direction X may be greater than or equal to 30°. The first direction X may be the direction perpendicular to the plane of the substrate 2. In such way, the light of the first interference sub-pixel 102 may appear at a large angle, such that the light of the first interference sub-pixel 102 may appear in the pictures with the large viewing angle, and the contents displayed on the display panel may be weakened, which may cause interference and realize the anti-peep effect. The display panel of the present disclosure may be not only suitable for standard RGB arrangement, but also suitable for diamond arrangement, which may make the product diversified and more practical.

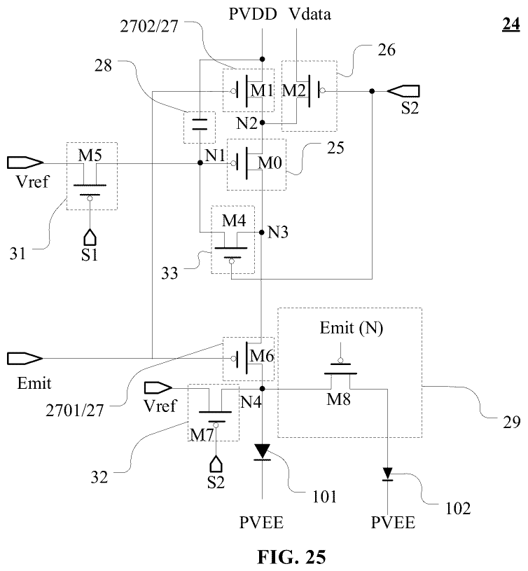

In some optional embodiments, referring to FIG. 25, FIG. 25 illustrates a schematic of a pixel circuit according to various embodiments of the present disclosure. The substrate may also include a pixel circuit 24. The pixel circuit 24 may include a drive module 25, a data write module 26, a light-emitting control module 27, a storage capacitor 28 and a selection control module 29.

The drive module 25 may be configured to generate drive current to drive the light-emitting element to emit light. The drive module 25 may include the drive transistor M0. The gate electrode of the drive transistor M0 may be electrically connected to the first node N1, the source electrode of the drive transistor M0 may be electrically connected to the second node N2, and the drain electrode of the drive transistor M0 may be electrically connected to the third node N3.

The data write module 26 may be configured to selectively provide a data signal to the drive transistor M0, and the output terminal of the data write module 26 may be electrically connected to the second node N2.

The light-emitting control module 27 may be configured to selectively allow the light-emitting element to enter a light-emitting stage. The light-emitting control module 27 may include a first light-emitting control module 2701. The first terminal of the first light-emitting control module 2701 may be electrically connected to the third node N3; the control terminal of the first light-emitting control module 2701 may be electrically connected to the first light-emitting signal terminal Emit; and the second terminal of the first light-emitting control module 2701 may be electrically connected to the light-emitting structure 3 of the first main sub-pixel 101 and the selection control module 29 respectively.

The first terminal of the selection control module 29 may be electrically connected to the second terminal of the first light-emitting control module 2701; the control terminal of the selection control module 29 may be electrically connected to the second light-emitting signal terminal Emit (N); and the second terminal of the selection control module 29 may be electrically connected to the light-emitting structure 3 of the first interference sub-pixel 102.

The storage capacitor 28 may be configured to maintain the potential of the control terminal of the drive module 25.

For example, the drive module 25 may be configured to generate a drive current to drive the light-emitting element to emit light. The drive module 25 may include the drive transistor M0. The gate electrode of the drive transistor M0 may be electrically connected to the first node N1, the source electrode of the drive transistor M0 may be electrically connected to the second node N2, and the drain electrode of the drive transistor M0 may be electrically connected to the third node N3.

The data write module 26 may be configured to selectively provide the data signal to the drive transistor M0. The output terminal of the data write module 26 may be electrically connected to the second node N2. The data write module 26 may include a second transistor M2. The gate electrode of the second transistor M2 may be connected to the second scan signal terminal S2, the first electrode of the second transistor M2 may be connected to a data voltage Vdata, and the second electrode of the second transistor M2 may be connected to the second node N2.

The light-emitting control module 27 may be configured to selectively allow the light-emitting element to enter the light-emitting stage. The light-emitting control module 27 may include the first light-emitting control module 2701. The first terminal of the first light-emitting control module 2701 may be electrically connected to the third node N3; the control terminal of the first light-emitting control module 2701 may be electrically connected to the first light-emitting signal terminal Emit; and the second terminal of the first light-emitting control module 2701 may be electrically connected to the light-emitting structure 3 of the first main sub-pixel 101 and the selection control module 29 respectively. Optionally, the first light-emitting control module 2701 may include a sixth transistor M6. The gate electrode of the sixth transistor M6 may be connected to the first light-emitting signal terminal, the source electrode of the sixth transistor M6 may be connected to the third node N3, and the drain electrode of the sixth transistor M6 may be connected to the light-emitting structure 3 of the first main sub-pixel 101. The light-emitting control module 27 may also include a second light-emitting control module 2702. The second light-emitting control module 2702 may include a first transistor M1. The gate electrode of the first transistor M1 may be connected to the first light-emitting signal terminal Emit, the source electrode of the first transistor M1 may be connected to a first power supply voltage PVDD, and the drain electrode of the first transistor M1 may be connected to the second node N2.

The first terminal of the selection control module 29 may be electrically connected to the second terminal of the first light-emitting control module 2701; the control terminal of the selection control module 29 may be electrically connected to the second light-emitting signal terminal Emit (N); and the second terminal of the selection control module 29 may be electrically connected to the light-emitting structure 3 of the first interference sub-pixel 102. For example, the selection control module 29 may include an eighth transistor M8. The gate electrode of the eighth transistor M8 may be connected to the second light-emitting signal terminal Emit (N); the source electrode of the eighth transistor M8 may be connected to the fourth node N4, that is, the second terminal of the first light-emitting control module 2701; and the drain electrode of the eighth transistor M8 may be electrically connected to the light-emitting structure 3 of the first interference sub-pixel 102.

Optionally, a first reset module 31, a second reset module 32 and a threshold compensation module 33 may be shown in the pixel circuit 24 of FIG. 25. The first reset module 31 may include a fifth transistor M5 to reset the gate electrode of the drive transistor M0. The gate electrode of the fifth transistor M5 may be connected to a first scan signal terminal S1, the source electrode of the fifth transistor M5 may be connected to a reset signal Vref, and the drain electrode of the fifth transistor M5 may be connected to the first node N1. The second reset module 32 may include a seventh transistor M7 to reset the light-emitting structure 3 of the first main sub-pixel 101. The source electrode of the seventh transistor M7 may be connected to a second scan signal terminal S2, the source electrode of the seventh transistor M7 may be connected to the reset signal Vref, and the drain electrode of the seventh transistor M7 may be connected to the light-emitting structure 3 of the first main sub-pixel 101. The threshold compensation module 33 may include a fourth transistor M4 to perform threshold compensation on the drive transistor M0. The gate electrode of the fourth transistor M4 may be connected to the second scan signal terminal S2, the first electrode of the fourth transistor M4 may be connected to the first node N1, and the second electrode of the fourth transistor M4 may be connected to the second node N2.

In one embodiment, the first transistor M1, the second transistor M2, the drive transistor M0, the fourth transistor M4, the fifth transistor M5, the sixth transistor M6, the seventh transistor M7 and the eighth transistor M8 may be P-type transistors, which may be merely taken as example for illustration. The P-type transistor is in conduction at a low potential and in disconnection at a high potential.

In one embodiment, by adding the selection control module 29, whether the light-emitting structure 3 of the first interference sub-pixel 102 emits light may be controlled. When the second light-emitting signal terminal Emit (N) controls the selection control module 29 to be turned on in conduction, the voltage at the fourth node N4 may be inputted to the light-emitting structure 3 of the first interference sub-pixel 102, and the light-emitting structure 3 of the first interference sub-pixel 102 may emit light. When the second light-emitting signal terminal Emit (N) controls the selection control module 29 to be turned off in disconnection, the voltage at the fourth node N4 cannot be inputted to the light-emitting structure 3 of the first interference sub-pixel 102, and the light-emitting structure 3 of the first interference sub-pixel 102 may not emit light. Obviously, in the display mode and the anti-peep mode, the first main sub-pixel 101 may both emit light.

In some optional embodiments, referring to FIG. 25, in the display mode, the selection control module 29 may be not in conduction; and in the anti-peep mode, the selection control module 29 may be in conduction.

In the display mode, the selection control module 29 may be not in conduction, the voltage at the fourth node cannot be inputted to the light-emitting structure 3 of the first interference sub-pixel 102, and the first interference sub-pixel 102 may not emit light. The first main sub-pixel 101 may emit light, and the first interference sub-pixel 102 may not emit light, such that the first sub-pixel 10 may display normally in the display mode. In the anti-peep mode, the selection control module 29 may be in conduction, the first interference sub-pixel 102 may emit light, and the first main sub-pixel 101 may emit light. The light emitted from the first interference sub-pixel 102 may exit at the large viewing angle from the light-exiting surface. The angle between the large viewing angle and the first direction X may be greater than or equal to 30°. The first direction X may be the direction perpendicular to the plane of the substrate 2. In such way, the light of the first interference sub-pixel 102 may appear at the large viewing angle. Therefore, the light emitted from the first interference sub-pixel 102 may appear in the pictures at the large viewing angle, and the contents displayed on the display panel may be weakened, which may cause interference and achieve the anti-peep effect.

Based on same inventive concept, the present disclosure provides a formation method of the display panel. As shown in FIG. 1, the display panel 100 may include the plurality of sub-pixels 1; the sub-pixel 1 may include the first sub-pixel 10, the second sub-pixel 20 and the third sub-pixel 30; at least the first sub-pixel 10 may include the first main sub-pixel 101 and the first interference sub-pixel 102; and the first interference sub-pixel 102 may at least partially surround the first main sub-pixel 101.

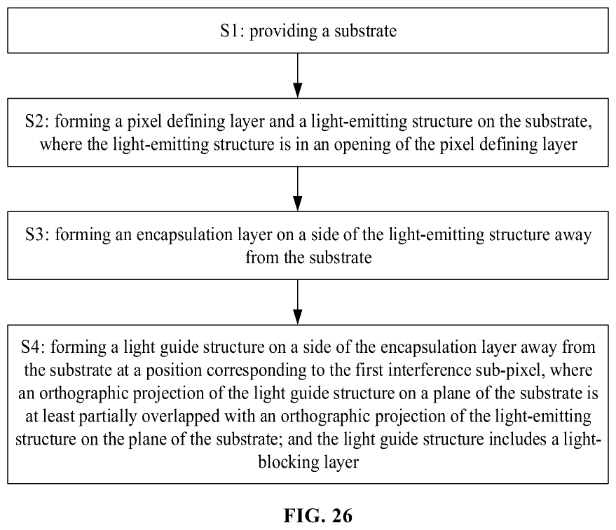

Referring to FIGS. 11 and 26, FIG. 26 illustrates a flowchart of a formation method of the display panel according to various embodiments of the present disclosure. The formation method may include following exemplary steps.

At S1, the substrate 2 may be provided.

At S2, the pixel defining layer 11 and the light-emitting structure 3 may be

formed on the substrate 2, and the light-emitting structure 3 may be in the opening of the pixel defining layer 11.

At S3, the encapsulation layer 8 may be formed on the side of the light-emitting structure 3 away from the substrate 2.

At S4, the light guide structure 15 may be formed on the side of the encapsulation layer 8 away from the substrate 2 at a position corresponding to the first interference sub-pixel 102; the orthographic projection of the light guide structure 15 on the plane of the substrate 2 and the orthographic projection of the light-emitting structure 3 on the plane of the substrate 2 may be at least partially overlapped with each other; and the light guide structure 15 may include the light-blocking layer 16.

For the formation method provided in the present disclosure, the substrate 2 including the pixel circuit may be formed first; and the pixel defining layer 11 and the light-emitting structure 3 may be formed on the substrate 2 subsequently. The light-emitting structure 3 may be in the opening of the pixel defining layer 11. Obviously, the light-emitting structure 3 formed at this time may correspond to the first sub-pixel 10, the second sub-pixel 20, and the third sub-pixel 30. The first sub-pixel 10 may also include the first interference sub-pixel 102 and the first main sub-pixel 101. Subsequently, the encapsulation layer 8 may be formed. Finally, the light guide structure 15 may be formed on the side of the encapsulation layer 8 away from the substrate 2 (as shown in FIG. 11). The light guide structure 15 may guide the light emitted from the first interference sub-pixel 102 to the large viewing angle. Therefore, in the anti-peep mode, the light emitted from the first interference sub-pixel 102 may appear in the pictures at the large viewing angle, and the contents displayed on the display panel may be weakened, which may cause interference and achieve the anti-peep effect.

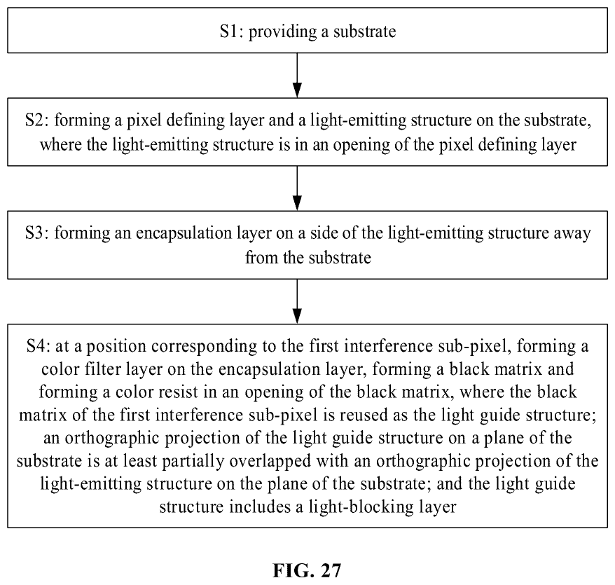

In some optional embodiments, referring to FIGS. 15 and 27, FIG. 27 illustrates another flowchart of a formation method of the display panel according to various embodiments of the present disclosure. The formation method may also include forming the color filter layer 17 on the encapsulation layer 8, forming the black matrix BM and forming the color resist 18 in the opening of the black matrix BM. The black matrix BM of the first interference sub-pixel 102 may be reused as the light guide structure 15.

It may be understood that organic self-light-emitting display panels need to be disposed with the polarizer on the side of the light-exiting surface to prevent reflection. However, after disposing the polarizers, the transmittance may be greatly reduced. In one embodiment, the color filter layer 17 may be formed on the side of the encapsulation layer 8 away from the substrate 2. In such way, the polarizers may be not disposed, and the color resist 18 may be disposed corresponding to the light-emitting region of sub-pixel 1 to achieve light filtering. The black matrix BM may be at the position corresponding to the gap of sub-pixel 1 to prevent reflection. The black matrix BM of the first interference sub-pixel 102 may be reused as the light guide structure 15. The material used in the black matrix BM may be an opaque material. The black matrix BM may be used as the light guide structure 15. When forming the black matrix BM, the light guide structure 15 may be formed. The light emitted from the light-emitting layer 13 of the first interference sub-pixel 102 cannot pass through the black matrix BM but exit along the outer edge of the black matrix BM, which may simplify the formation process.

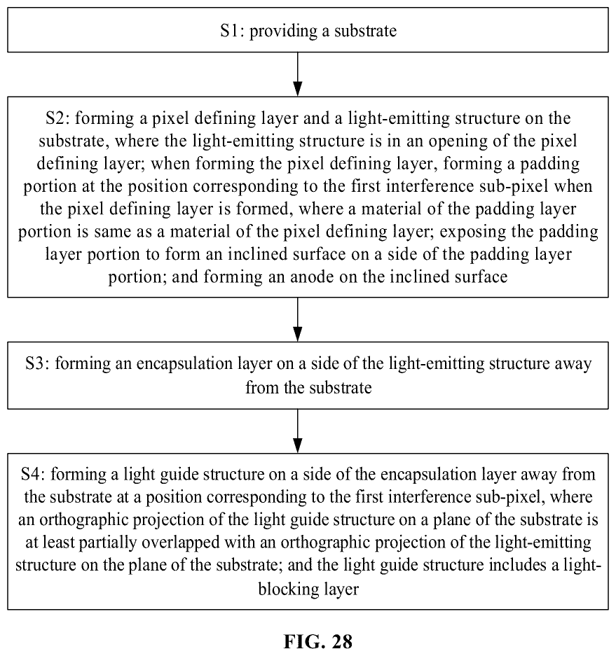

In some optional embodiments, referring to FIG. 28, FIG. 28 illustrates another flowchart of a formation method of the display panel according to various embodiments of the present disclosure. While forming the pixel defining layer 11, the padding layer portion 22 may be formed at the position corresponding to the first interference sub-pixel 102, where the material of the padding layer portion 22 may be same as the material of the pixel defining layer 11; exposure may be performed on the padding layer portion 22, such that the side surface of the padding layer portion 22 may form a inclined surface; and the anode 12 may be formed on the inclined surface.

For example, the light-emitting structure 3 may include the anode 12, the light-emitting layer 13 and the cathode 14 which are arranged sequentially along the plane perpendicular to the substrate 2. In one embodiment, the padding layer portion 22 may be formed while forming the pixel defining layer 11 (as shown in FIGS. 21-23). The padding layer portion 22 may include the inclined surface inclined along the fourth direction U/U′. Next, the anode 12 may be formed on the side of the padding layer portion 22 away from the substrate 2. The anode 12 may cover the side of the inclined surface away from the substrate 2, such that the inclined surface 23 inclined along the fourth direction U/U′ may be formed at the anode 12. The light emitted from the first interference sub-pixel 102 may be perpendicular to the inclined surface. Therefore, the inclined surface may further guide the light of the first interference pixel to the large viewing angle to enhance the anti-peep effect. Since the padding layer portion 22 and the pixel defining layer 11 are formed simultaneously, the formation process may be simplified.

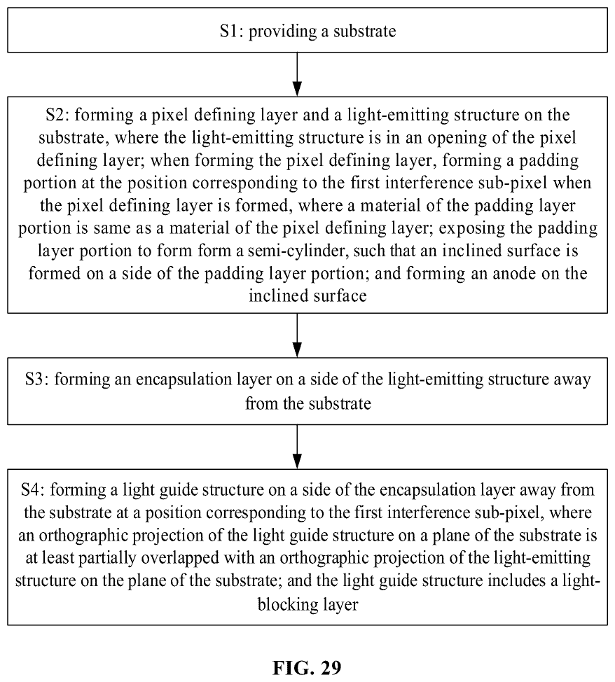

In some optional embodiments, referring to FIG. 29, FIG. 29 illustrates another flowchart of a formation method of the display panel according to various embodiments of the present disclosure. The padding layer portion 22 may be exposed to form a semi-cylinder.

Referring to FIG. 29, after the padding layer portion 22 is exposed to form the semi-cylinder, the inclined surface of the anode 12 may be a semicircle. The light emitted from the first interference sub-pixel 102 may be perpendicular to the inclined surface or have a certain angle with the inclined surface. Therefore, the inclined surface may further guide the light of the first interference pixel to the large viewing angle to enhance the anti-peep effect.

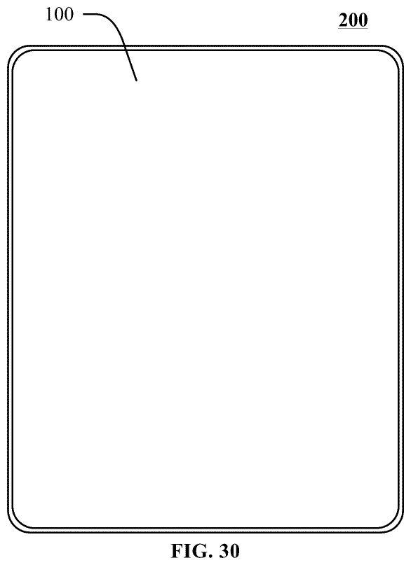

Based on a same inventive concept, the present disclosure further provides a display apparatus 200. Referring to FIG. 30, FIG. 30 illustrates a structural schematic of a display apparatus according to various embodiments of the present disclosure. The display apparatus 200 provided in one embodiment may include the display panel 100 in above-mentioned embodiments. A mobile phone may be taken as an example to illustrate the display apparatus 200 in one embodiment shown in FIG. 30. It may be understood that the display apparatus 200 provided by embodiments of the present disclosure may be a computer, a television, an electronic paper, a vehicle-mounted display apparatus, or other display apparatus with a display function, which may not be limited in the present disclosure. The display apparatus 200 provided by embodiments of the present disclosure may have the beneficial effects of the display panel 100 provided by embodiments of the present disclosure, which may not be described in detail herein.

It may be seen from above-mentioned embodiments that the display panel, the formation method, and the display apparatus provided by the present disclosure at least achieve the following beneficial effects.

In the display panel provided by the present disclosure, the sub-pixel includes the first sub-pixel, the second sub-pixel and the third sub-pixel; the first sub-pixel, the second sub-pixel and the third sub-pixel emit light of different colors; the sub-pixel includes the substrate, the light-emitting structure on the side of the substrate, and the encapsulation layer on the side of the light-emitting structure away from the substrate; at least the first sub-pixel includes the first main sub-pixel and the first interference sub-pixel; and the first interference sub-pixel at least partially surrounds the first main sub-pixel. In the display mode, the first main sub-pixel emits light, and the first interference sub-pixel does not emit light. Therefore, the first sub-pixel may display normally in the display mode. In the anti-peep mode, both the first main sub-pixel and the first interference sub-pixel emit light. The light emitted from the first interference sub-pixel exits at the large viewing angle from the light-exiting surface. The angle between the large viewing angle and the first direction is greater than or equal to 30°. The first direction is the direction perpendicular to the plane of the substrate. In such way, the light emitted from the first interference sub-pixel may appear at the large viewing angle. Therefore, the light emitted from the first interference sub-pixel may appear in the pictures at the large viewing angle, and the contents displayed on the display panel may be weakened, which may cause interference and achieve the anti-peep effect.

Although some embodiments of the present disclosure have been described in detail through various embodiments, those skilled in the art should understand that above embodiments may be for illustration only and may not be intended to limit the scope of the present disclosure. Those skilled in the art should understood that modifications may be made to above embodiments without departing from the scope and spirit of the present disclosure. The scope of the present disclosure may be defined by the appended claims.

What is claimed is:

1. A display panel, comprising:
a plurality of sub-pixels, wherein a sub-pixel of the plurality of sub-pixels includes a first sub-pixel, a second sub-pixel, and a third sub-pixel; the first sub-pixel, the second sub-pixel, and the third sub-pixel emit light of different colors; the sub-pixel of the plurality of sub-pixels includes a substrate, a light-emitting structure on a side of the substrate, and an encapsulation layer on a side of the light-emitting structure away from the substrate; at least the first sub-pixel includes a first main sub-pixel and a first interference sub-pixel; and the first interference sub-pixel at least partially surrounds the first main sub-pixel; and
a display mode and an anti-peep mode during operation, wherein:
in the display mode, the first main sub-pixel emits light, and the first interference sub-pixel does not emit light; and
in the anti-peep mode, both the first main sub-pixel and the first interference sub-pixel emit light, wherein the first interference sub-pixel emits light at a wide viewing angle from a light-exiting surface, an angle between the large viewing angle and a first direction is greater than or equal to 30°, and the first direction is a direction perpendicular to a plane of the substrate.

2. The display panel according to claim 1, wherein:
an area of the first interference sub-pixel is S1, an area of the first main sub-pixel is S2, and S1≤½×S2.

3. The display panel according to claim 1, wherein:
at least a part of first interference sub-pixels and at least a part of first main sub-pixels are arranged along a second direction or a third direction, wherein the second direction is a row direction, the third direction is a column direction, and the second direction intersects the third direction; and/or
orthographic projections of at least a part of first interference sub-pixels on the plane of the substrate surround an orthographic projection of the first main sub-pixel on the plane of the substrate; and/or
at least a part of first interference sub-pixels and at least a part of first main sub-pixels are arranged at vertex corners.

4. The display panel according to claim 1, wherein:
along a second direction, in two adjacent first sub-pixels, a first main sub-pixel of one first sub-pixel is adjacent to a first interference sub-pixel of another first sub-pixel adjacent to the one first sub-pixel along the second direction;
along a third direction, in two adjacent first sub-pixels, a first main sub-pixel of one first sub-pixel is adjacent to a first main sub-pixel of another first main sub-pixel adjacent to the one first sub-pixel along the third direction; and a first interference sub-pixel of the one first sub-pixel is adjacent to a first interference sub-pixel of the another first sub-pixel adjacent to the one first sub-pixel along the third direction; and
the second direction is a row direction, the third direction is a column direction, and the second direction intersects the third direction.

5. The display panel according to claim 1, wherein:
in the first interference sub-pixel, a light guide structure is on a side of the encapsulation layer away from the light-emitting structure; an orthographic projection of the light guide structure on the plane of the substrate is at least partially overlapped with an orthographic projection of the light-emitting structure on the plane of the substrate; and the light guide structure includes a light-blocking layer.

6. The display panel according to claim 5, wherein:
in the first main sub-pixel, along the first direction, a maximum distance between the light guide structure and the light-emitting structure is L, and a width of the light-emitting structure along a second direction or a third direction is W, wherein tan30°≤W/L≤ tan45°, the second direction is a row direction, the third direction is a column direction, and the second direction intersects the third direction.

7. The display panel according to claim 5, wherein:
the sub-pixel further includes a color filter layer on a side of the encapsulation layer away from the substrate; the color filter layer includes a black matrix and a color resist in an opening of the black matrix; a material of the light guide structure is same as a material of the black matrix.

8. The display panel according to claim 7, wherein:
the light guide structure is on a side of the black matrix away from the substrate.

9. The display panel according to claim 7, wherein:
the black matrix is reused as the light guide structure.

10. The display panel according to claim 9, wherein:
a cross section of the light guide structure is an inverted trapezoid.

11. The display panel according to claim 8, wherein:
the light-emitting structure further includes an anode, a light-emitting layer and a cathode arranged sequentially along the plane perpendicular to the plane of the substrate; a groove is between an anode of the first interference sub-pixel and an anode of the first main sub-pixel; and
an orthographic projection of the groove on the plane of the substrate is at least partially overlapped with an orthographic projection of the black matrix on the plane of the substrate.

12. The display panel according to claim 11, wherein:
the substrate includes a base substrate and a data line at the base substrate adjacent to the light-emitting structure; the data line provides a data voltage to the sub-pixel; and an orthographic projection of the data line on a plane of the base substrate is within an orthographic projection of the groove on the plane of the base substrate.

13. The display panel according to claim 8, wherein:
a maximum viewing angle of the first main sub-pixel is θ; a width of the black matrix between the first main sub-pixel and the first interference sub-pixel along a fifth direction is c; and in the first interference sub-pixel, a maximum distance between the light guide structure and the light-emitting structure along the first direction is L1, and L2 is a partial length of the color resist between an end of the black matrix and an adjacent end of the light-emitting structure along the fifth direction, wherein:
tan (θ/2)=(L2+c)/L1; and the fifth direction is a direction pointing from the first main sub-pixel to the first interference sub-pixel.

14. The display panel according to claim 1, wherein:
in the first interference sub-pixel, the light-emitting structure further includes an anode; the anode includes an inclined surface which is inclined along a fourth direction; an angle β is between the fourth direction and the first direction; and β>0°.

15. The display panel according to claim 14, wherein:
the inclined surface of the anode is an arc-shaped surface.

16. The display panel according to claim 14, wherein:
a cross-section of the anode is semicircular.

17. The display panel according to claim 14, wherein:
the light-emitting structure further includes a padding layer portion on a side of the anode adjacent to the substrate; the padding layer portion includes an inclined surface which is inclined along the fourth direction; and the anode covers a side of the inclined surface away from the substrate.

18. The display panel according to claim 14, wherein:
a color of light emitted from the first sub-pixel is green.

19. The display panel according to claim 1, wherein:
the display panel includes a plurality of pixel repeating units arranged in an array; and a pixel repeating unit of the plurality of pixel repeating units includes two second sub-pixels, two third sub-pixels and four first sub-pixels;
in a same pixel repeating unit, two second sub-pixels and two third sub-pixels are arranged in two rows and two columns, and colors of light emitted from two sub-pixels arranged in a same row or column are different;
geometric centers of the two second sub-pixels and geometric centers of the two third sub-pixels form a first virtual quadrilateral, and a first sub-pixel is inside the first virtual quadrilateral; and
geometric centers of the four first sub-pixels form a second virtual quadrilateral, and a second sub-pixel or a third sub-pixel is inside the second virtual quadrilateral.

20. The display panel according to claim 1, wherein:
the substrate further includes a pixel circuit including a drive module, a data write module, a light-emitting control module, a storage capacitor and a selection control module, wherein:
the drive module is configured to generate a drive current for driving the light-emitting element to emit light, wherein the drive module includes a drive transistor, a gate electrode of the drive transistor is electrically connected to a first node, a source electrode of the drive transistor is electrically connected to a second node, and a drain electrode of the drive transistor is electrically connected to a third node;
the data write module is configured to selectively provide a data signal to the drive transistor, wherein an output terminal of the data write module is electrically connected to the second node;
the light-emitting control module is configured to selectively allow the light-emitting element to enter a light-emitting stage, wherein the light-emitting control module includes a first light-emitting control module, a first terminal of the first light-emitting control module is electrically connected to the third node, a control terminal of the first light-emitting control module is electrically connected to a first light-emitting signal terminal, and a second terminal of the first light-emitting control module is electrically connected to the light-emitting structure of the first main sub-pixel and the selection control module respectively;
a first terminal of the selection control module is electrically connected to the second terminal of the first light-emitting control module, a control terminal of the selection control module is electrically connected to a second light-emitting signal terminal, and a second terminal of the selection control module is electrically connected to the light-emitting structure of the first interference sub-pixel; and
the storage capacitor is configured to maintain a potential of a control terminal of the drive module.

21. The display panel according to claim 20, wherein:
in the display mode, the selection control module is not in conduction; and in the anti-peep mode, the selection control module is in conduction.

22. A formation method of a display panel, wherein the display panel includes a plurality of sub-pixels, wherein a sub-pixel of the plurality of sub-pixels include a first sub-pixel, a second sub-pixel, and a third sub-pixel; at least the first sub-pixel includes a first main sub-pixel and a first interference sub-pixel; and the first interference sub-pixel at least partially surrounds the first main sub-pixel, the method comprising:
providing a substrate;
forming a pixel defining layer and a light-emitting structure on the substrate, wherein the light-emitting structure is in an opening of the pixel defining layer;
forming an encapsulation layer on a side of the light-emitting structure away from the substrate; and
at a position corresponding to the first interference sub-pixel, forming a light guide structure on a side of the encapsulation layer away from the substrate, wherein an orthographic projection of the light guide structure on a plane of the substrate is at least partially overlapped with an orthographic projection of the light-emitting structure on the plane of the substrate; and
the light guide structure includes a light-blocking layer.

23. The formation method according to claim 22, further including:
forming a color filter layer on the encapsulation layer, forming a black matrix, and forming a color resist in an opening of the black matrix, wherein a black matrix of the first interference sub-pixel is reused as the light guide structure.

24. The formation method according to claim 22, further including:
forming a padding layer portion at the position corresponding to the first interference sub-pixel when the pixel defining layer is formed, wherein a material of the padding layer portion is same as a material of the pixel defining layer; and exposing the padding layer portion to form an inclined surface on a side of the padding layer portion; and
forming an anode on the inclined surface.

25. The formation method according to claim 24, wherein:
the padding layer portion is exposed to form a semi-cylinder.

26. A display apparatus, comprising:
a display panel, comprising:
a plurality of sub-pixels, wherein a sub-pixel of the plurality of sub-pixels includes a first sub-pixel, a second sub-pixel, and a third sub-pixel; the first sub-pixel, the second sub-pixel, and the third sub-pixel emit light of different colors; the sub-pixel of the plurality of sub-pixels includes a substrate, a light-emitting structure on a side of the substrate, and an encapsulation layer on a side of the light-emitting structure away from the substrate; at least the first sub-pixel includes a first main sub-pixel and a first interference sub-pixel; and the first interference sub-pixel at least partially surrounds the first main sub-pixel; and
a display mode and an anti-peep mode during operation, wherein:
in the display mode, the first main sub-pixel emits light, and the first interference sub-pixel does not emit light; and
